(19) United States
(12) Patent Application Publication
(10) Pub. No.: US 2006/0208320 A1
(43) Pub. Date: Sep. 21, 2006

(54) MIS-type semiconductor device

(75) Inventors: Yoshinori Tsuchiya, Yokohama-shi (JP); Masato Koyama, Miura-gun (JP); Hirotaka Nishino, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/230,823

(22) Filed: Sep. 21, 2005

(30) Foreign Application Priority Data
Mar. 15, 2005 (JP) 2005-073733

(51) Int. Cl. H01L 29/76; H01L 21/3205

(52) U.S. Cl. 257/371; 257/E27.062; 257/E27.067; 257/412; 438/585

(57) ABSTRACT

A MIS-type semiconductor device is configured with a semiconductor substrate, and a p-type MIS transistor, and a n-type MIS transistor which is provided on the semiconductor substrate, the p-type MIS transistor including a gate electrode which is made of Ge and one element which is selected from the group consisting of Ta, V and Nb.

### CROSS-REFERENCE TO RELATED APPLICATIONS

This application is based upon and claims the benefit of priority from prior Japanese Patent Application No. 2005-073733, filed Mar. 15, 2005, the entire contents of which are incorporated herein by reference.

### BACKGROUND OF THE INVENTION

1. Field of the Invention

The present invention relates to a semiconductor device that incorporates metal insulator semiconductor (MIS) transistors. In particularly, the invention relates to a semiconductor device in which MIS transistors have a gate electrode made of metal.

2. Description of the Related Art

To enhance the performance of a semiconductor integrated circuit, it is necessary to improve the performance of MOS devices, i.e., the elements provided in the circuit. The performance of MOS devices has been improved, basically in accordance with the scaling low. In recent years, however, it has become difficult to improve the performance of the MOS device by making it smaller, due to various physical limitations to the microelectronic techniques.

One thing that makes it difficult to improve the performance of each MOS device is the depletion in the polycrystalline Si gate electrode. The depletion suppresses the scaling low of thickness of the gate insulating film. Hitherto, the performance of MOS device has been improved by reducing the thickness of the gate insulating film, namely thanks to the scaling low. However, it is now increasing difficult to reduce the thickness of the gate insulating film, due to the depletion in the polycrystalline Si gate electrode and the inversion layer existing in the MOS device. In the technical generation wherein the gate oxide film is less than 1 nm thick, the depletion capacitance of the polycrystalline Si gate electrode is as much as 30% of the capacitance of oxide film.

The depletion capacitance can be decreased by replacing the polycrystalline Si gate electrode with a metal gate electrode. The metal gate electrode must be made of metal material whose work function changes in accordance with the conductivity type of the MOS device. Metal materials desirable for gate electrodes of the MOS devices of either conductivity type have been reported. They have work functions similar to that of polycrystalline Si. (See S. B. Samavedam et al., Mat. Res. Soc. Symp. Proc. Vol. 716 (2002) 85 and C. H. Huang et al., Int. Electron. Devices Meet. 2003, p. 319.) These metal materials are totally different in their constituent elements, depending on the conductivity type of the MOS device. This complicates the process of manufacturing a semiconductor integrated circuit incorporating MOS devices, and inevitably increases the manufacturing cost of the circuit.

As pointed out above, the performance of the device decreases due to the depletion in the polycrystalline Si gate electrodes. In view of this, it is desired that a metal electrode having electron density higher than that of polycrystalline Si by about two orders be used as gate electrode or be provided at the interface between the gate electrode and the gate insulating film. In either case, the metal material needs to exhibit one work function in an n-type transistor and another work function in a p-type transistor, so that the transistor may have an appropriate threshold value. The work function required greatly depends on whether the device is one for use in high-speed logic circuits or in low-power-consumption circuits. Any metal material has a unique work function, however. Hence, one metal material must be used in n-type devices, and another metal material in p-type devices. This complicates the process of manufacturing a semiconductor integrated circuit incorporating MOS devices, and inevitably increases the manufacturing cost of the circuit.

### BRIEF SUMMARY OF THE INVENTION

According to an aspect of this invention, there is provided a MIS-type semiconductor device comprising:

a semiconductor substrate; and

a p-type MIS transistor which is provided on the semiconductor substrate and which has a gate electrode containing Ge and one element selected from the group consisting of Ta, V and Nb.

According another aspect of this invention, there is provided a MIS-type semiconductor device comprising:

a semiconductor substrate;

a p-type MIS transistor which is provided on the semiconductor substrate and which has a gate electrode containing Ge and one element selected from the group consisting of Ta, V and Nb; and

an n-type MIS transistor which is provided on the semiconductor substrate.

According to still another aspect of this invention, there is provided a complementary MIS semiconductor device comprising:

a semiconductor substrate;

an n-type well layer which is formed on the semiconductor substrate;

a p-type well layer which is formed on the semiconductor substrate;

an element-isolating insulating film formed on the semiconductor substrate to isolate the p-type well layer and the n-type well layer from each other;

a p-type MIS transistor which contains a gate electrode provided on an gate insulating film formed on the n-type well layer, and a p-type source-drain region formed in the n-type well layer, the gate electrode being made of Ta germanide; and

an n-type MIS transistor which has a gate electrode provided on an gate insulating film formed on the p-type well layer, and an n-type source-drain region formed in the p-type well layer, the gate electrode of the n-type MIS transistor being made of Ta silicide.

### BRIEF DESCRIPTION OF THE SEVERAL VIEWS OF THE DRAWING

FIG. 1 is a sectional view schematically showing a MIS-type semiconductor device according to a first embodiment of the present invention;

FIG. 2 is a diagram representing the gate-leakage current characteristic of Ta germanide and the gate-leakage current characteristic of Ni germanide, both observed at 600° C.;

FIG. 3 is a diagram representing a relation between the work function of a gate electrode for use in the 30-nm generation technology, on the one hand, and the experimentally obtained work function of Ta-based compound and the work function of Al;

FIG. 4 is a characteristic diagram showing how a flat-band voltage depends on the thickness of oxide film in a MIS capacitor;

FIG. 5 is a graph representing the X-ray diffraction spectra that Ta germanide exhibits at different heat-treatment temperatures;

FIG. 6 is a sectional view schematically depicting the structure of a modification of the first embodiment;

FIG. 7 is a sectional view schematically depicting the structure of another modification of the first embodiment;

FIG. 8 is a sectional view schematically showing the structure of a MIS-type semiconductor device according to a second embodiment of the invention;

FIG. 9 is a sectional view schematically depicting the structure of a modification of the second embodiment;

FIG. 10 is a sectional view schematically depicting the structure of another modification of the second embodiment;

FIG. 11 is a sectional view schematically showing the structure of a MIS-type semiconductor device according to a third embodiment of this invention;

FIG. 12 is a sectional view schematically showing the structure of a modification of the third embodiment;

FIG. 13 is a sectional view schematically showing the structure of a MIS-type semiconductor device according to a fourth embodiment of the present invention;

FIG. 14 is a sectional view schematically depicting the structure of a modification of the fourth embodiment;

FIG. 15 is a sectional view schematically illustrating the structure of another modification of the fourth embodiment;

FIG. 16 is a sectional view schematically illustrating the structure of still another modification of the fourth embodiment;

FIG. 17 is a sectional view schematically showing the structure of a MIS-type semiconductor device according to a fifth embodiment of this invention;

FIG. 18 is a sectional view schematically depicting the structure of a modification of the fifth embodiment;

FIG. 19 is a sectional view schematically depicting the structure of another modification of the fifth embodiment;

FIG. 20 is a sectional view schematically showing the structure of a MIS-type semiconductor device according to a sixth embodiment of the present invention;

FIG. 21 is a sectional view schematically depicting the structure of a modification of the sixth embodiment;

FIG. 22 is a sectional view schematically depicting the structure of another modification of the sixth embodiment;

FIGS. 23A to 23D are sectional views illustrating a method of manufacturing a MIS-type semiconductor device according to a seventh embodiment of this invention;

FIGS. 24A to 24D are sectional views showing a method of manufacturing a MIS-type semiconductor device according to an eighth embodiment of this invention;

FIGS. 25A to 25D are sectional views illustrating a method of manufacturing a MIS-type semiconductor device according to a ninth embodiment of the invention;

FIGS. 26A to 26D are sectional views showing a method of manufacturing a MIS-type semiconductor device according to a tenth embodiment of the invention;

FIGS. 27A to 27D are sectional views showing a method of manufacturing a MIS-type semiconductor device according to an eleventh embodiment of the invention;

FIGS. 28A to 28D are sectional views illustrating a method of manufacturing a MIS-type semiconductor device according to an twelfth embodiment of this invention;

FIGS. 29A to 29D are sectional views showing a method of manufacturing a MIS-type semiconductor device according to a twelfth embodiment of the invention;

FIGS. 30A to 30D are sectional views showing another method of manufacturing a MIS-type semiconductor device according to the twelfth embodiment of the invention;

FIGS. 31A to 31D are sectional views depicting another method of manufacturing a MIS-type semiconductor device according to a thirteenth embodiment of this invention;

FIG. 32 is a perspective view schematically showing the structure of a FIN-type semiconductor device according to a fourteenth embodiment of this invention; and

FIGS. 33A to 33C are perspective views showing a method of manufacturing a FIN-type semiconductor device according to a fifteenth embodiment of the present invention.

### DETAILED DESCRIPTION OF THE INVENTION

The present invention will be described in detail, with reference to the embodiments shown in the accompanying drawings.

### First Embodiment

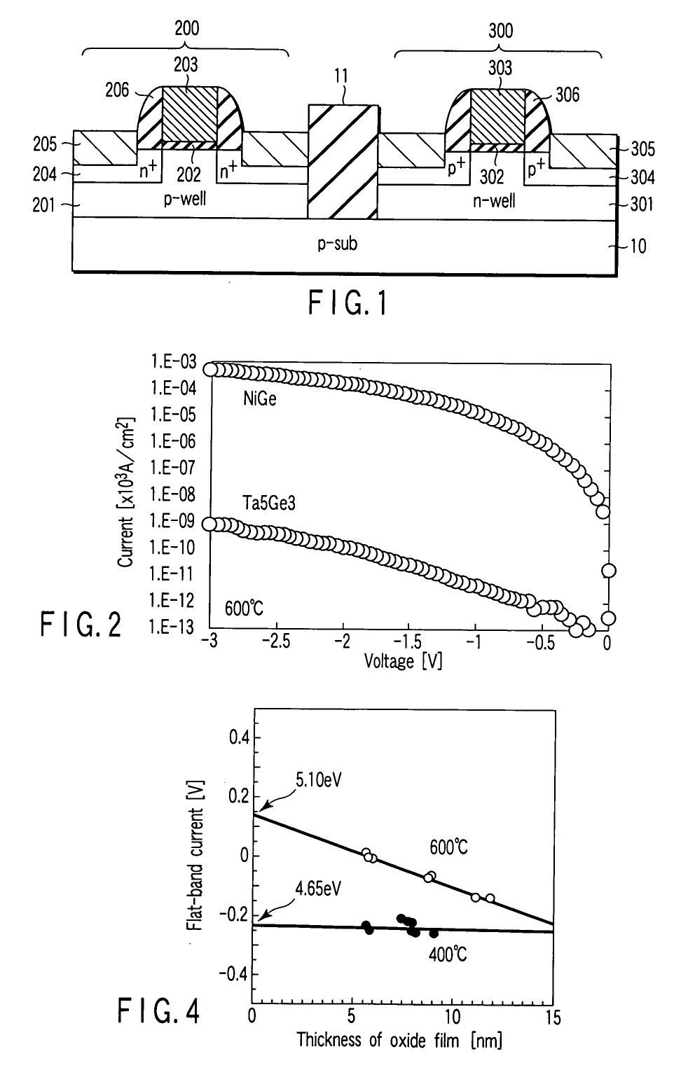

FIG. 1 is a sectional view schematically showing a MIS-type semiconductor device according to the first embodiment of the invention.

A p-type impurity region (p-type well) 201 and an n-type impurity region (n-type well) 301 are provided in the surface of a p-type Si substrate 10. The regions 201 and 301 are spaced apart by an Si oxide film (element-isolating film) 11. A gate insulating film 202 is formed on a part of the p-type well 201. Similarly, a gate insulating film 302 is formed on a part of the n-type well 301. The gate insulating films 202 and 302 are ordinary thermally oxidized Si films. Preferably, they are 2 nm or less thick. A gate electrode 203 is formed on the gate insulating film 202. Similarly, a gate electrode 303 is formed on the gate insulating film 302. The gate-electrodes 203 and 303 are made of Ta germanide, which is a compound of Ta (tantalum) and Ge (germanium).

It is desired that the distance (i.e., gate length) between the source and drain of the gate structure composed of the gate insulating film 202 and gate electrode 203 should be 50 nm or less. Similarly, it is desired that the distance (i.e., gate length) between the source and drain of the gate structure composed of the gate insulating film 302 and gate electrode 303 should be 50 nm or less.

Above the p-type well 201, a source region and a drain region, both formed in an n-type, high-concentration impurity region 204, are provided on the respective side of the gate insulating film 202. On the impurity region 204, an Ni silicide layer 205 is formed. The Ni silicide layer 205 serves as a contact electrode. Thus, an n-type MOS transistor 200 is formed in the p-type well 201.

Above the n-type well 301, a source region and a drain region, both formed in a p-type, high-concentration impurity region 304, are provided on the respective side of the gate insulating film 302. On the impurity region 304, an Ni silicide layer 305 is formed. The Ni silicide layer 305 serves as contact material. Thus, a p-type MOS transistor 300 is formed in the n-type well 301. In FIG. 1, reference numerals 206 and 306 denote sidewall insulating films.

FIG. 2 shows the gate-leakage current characteristic of Ta germanide, in comparison with that of Ni germanide. When Ta germanide is used, the gate leakage current can be smaller by about six orders, than in the case where Ni germanide is used. The leakage current in Ni germanide results from the diffusion of atoms from the gate electrode. This means that Ta germanide is more stable than Ni germanide on any insulating film. Thus, a gate electrode made of Ta germanide can suppress the diffusion of atoms from the electrode, to prevent the device from being degraded in characteristic, e.g., the mobility of electrons and holes, and in operating reliability. Therefore, Ta germanide helps to provide C-MOS devices of high performance and high reliability. Instead of Ta germanium, V and Nb can be used, because these metals are elements of the same group as Ta and similar to Ta in terms of chemical properties.

A C-MOS device in which the n-type MOS transistor 200 and p-type MOS transistor 300 operate complementarily to each other can be manufactured, providing various types of LSIs, by such a simple method as will be described below.

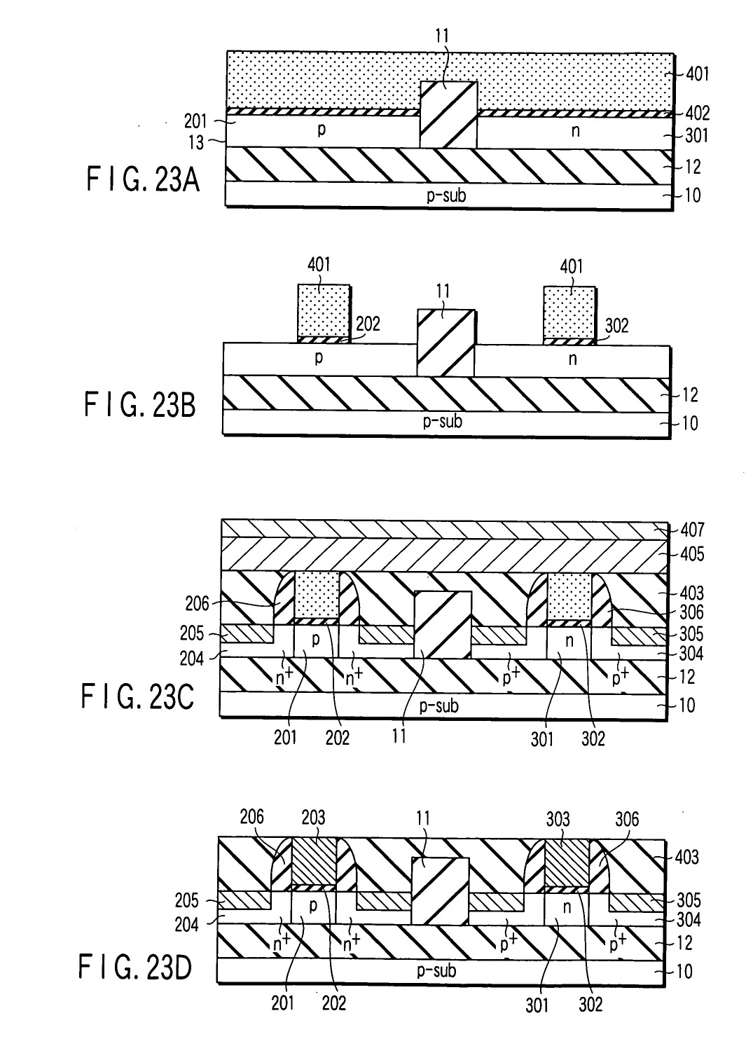

In the first embodiment, the n-type MOS transistor 200 and p-type MOS transistor 300 operate complementarily, thus constituting a C-MOS device. The gate electrodes in both n-type MOS transistor 200 and the p-type MOS transistor 300 have the same kind of Ta germanide. As will be described later in detail with reference to FIG. 23, Ta germanide made at a low-temperature heat treatment (at 500° C. or less) has an effective work function (φeff) of 4.6±0.1 eV. The effective work function is one at the interface between the electrode and insulating film of a MOS capacitor. Generally, this value can be determined from the capacitance-voltage or current-voltage characteristic of the MOS capacitor. Here, it is called “effective work function,” distinguished from the vacuum work function that a layer of any material has at its surface with respect to a vacuum.

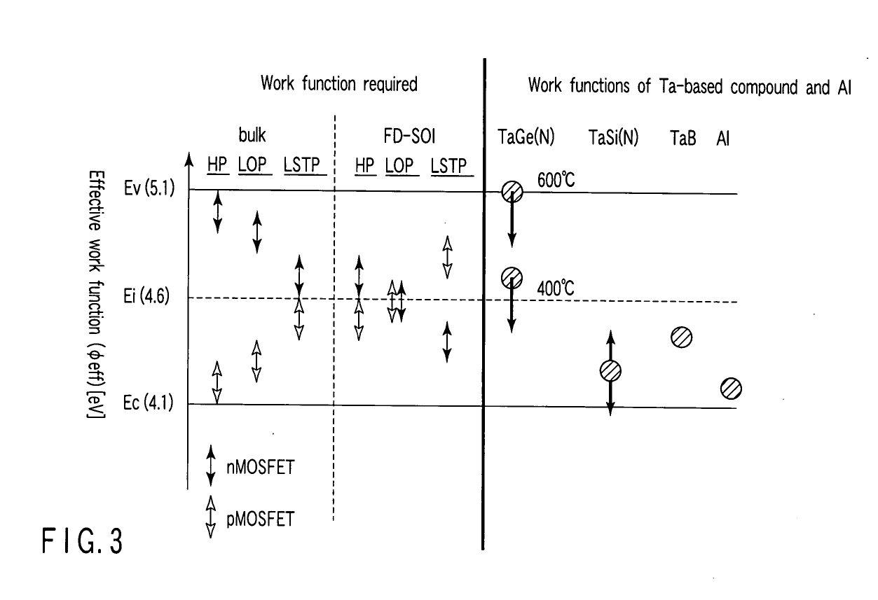

The threshold voltage of a transistor can be controlled by changing the effective work function φeff of its gate electrode and the impurity concentration of its channel. For a transistor for use in the 50-nm generation technology, the impurity distribution in the channel must be precisely controlled in order to suppress the short-channel effect. To this end, it is desirable to adjust the threshold value of the transistor in accordance with the effective work function φeff of the gate electrode. The 50-nm generation technology requires various effective work functions φeff for transistors that have different operating threshold voltages, as is illustrated in FIG. 3. In FIG. 3, HP denotes a low-threshold, high-performance transistor for use in sever LSIs, LOP a low-operation-power transistor for use in PCs, and LSTP a low-stand-by, power transistor for use mainly in mobile apparatuses.

The effective work function (φeff) that a transistor formed on an ordinary Si substrate must have is 4.1 to 4.3 eV if the transistor is an nMOS HP transistor, and is 4.9 to 5.4 eV if the transistor is a pMOS HP transistor. The effective work function (φeff) is 4.2 to 4.4 eV if the transistor is an nMOS LOP transistor, and is 4.7 to 4.9 eV if the transistor is a PMOS LOP transistor. The effective work function (φeff) is 4.4 to 4.6 eV if the transistor is an nMOS LSTP transistor, and is 4.6 to 4.8 eV if the transistor is a pMOS LSTP transistor. To provide transistors of these types, a technique and a material are require, which can control the function φeff within the range from 4 eV to 5 eV at the end of the Si forbidden band or within a range near the Si mid-gap.

FIG. 4 shows the effective work function (φeff) determined from the relation of flat-band voltage of a MOS capacitor having a gate electrode made of Ta germanide to the oxide-film-thickness, and the temperature at which the gate electrode was formed. The gate electrode was formed by forming a Ge film and a Ta film, in this order, and then by heating these films, subjecting them to solid-phase reaction. The ratio in thickness of the Ta film to the Ge film was 1:2. The function φeff of Ta germanide can be easily controlled. If the gate electrode is formed at lower temperatures, φeff=4.6±0.1 eV. If the gate electrode is formed at 400° C. or more, the effective work function will change to 5.1±0.1 eV.

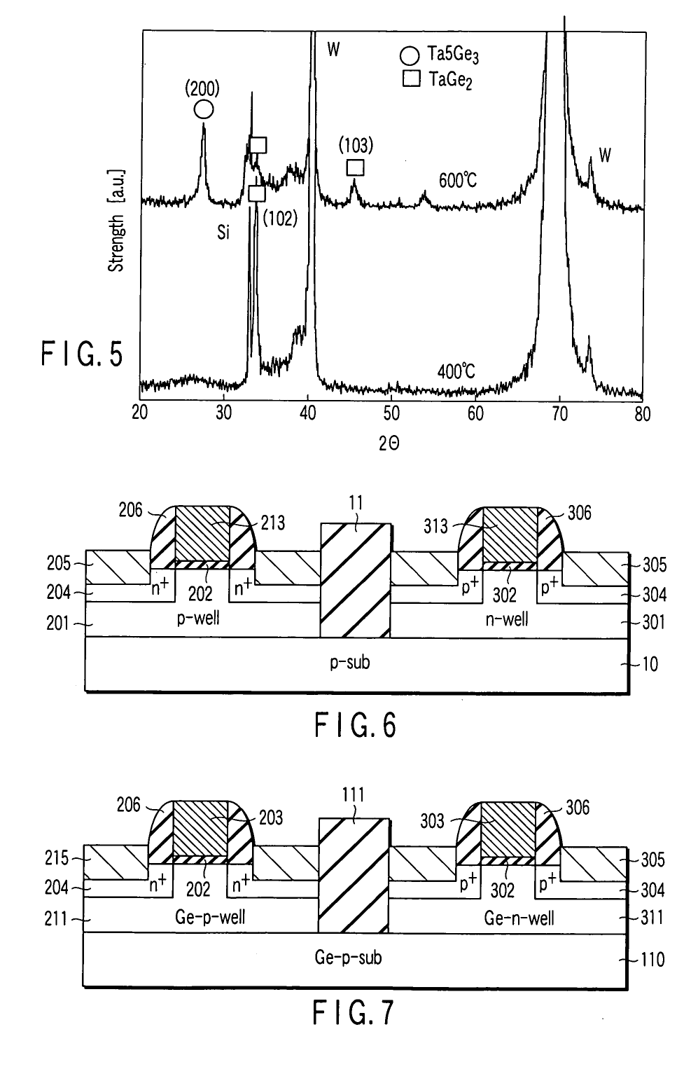

This is because Ta germanide exhibits one crystallinity at a relatively low temperature and another crystallinity at a relatively high temperature, as seen from FIG. 5. As FIG. 5 shows, a TaGa₂ layer formed at a low temperature (400° C.) exhibits prominent orientation with respect to an insulating film, contacting the insulating film at its (102) face. Since the atom density is relatively low at the (102) face that contacts the insulating film, the effective work function φeff is relatively small. By contrast, a TaGa₂ layer formed at a high temperature (600° C. or more) exhibits little orientation with respect to the insulating film. Not only TaGa₂, but also TaGa₃ is formed. The layer consists of tiny crystal grains that are not orientated in a specific direction. As a result, the effective work function increases.

Thus, an effective work function φeff ranging from the Si mid-gap to the Si valence band edge can be easily attained, by using only one material, i.e., Ta germanide, and by controlling the temperature at which this material is formed. This advantage greatly simplifies the method of manufacturing C-MOS devices as will be described later in conjunction with the method. The effective work function φeff of germanide can be easily modulated by introducing impurity elements (B, As, P, Sb, S, Al and In) that are dopants in Ge to the interface, like the effective work function of silicide. Unlike silicide, however, germanide has its effective work function decreased even if B is introduced to the interface. Its effective work function φeff can be modulated, but to 4 eV at most. How much the effective work function φeff is modulated is determined by the amount in which the impurities are segregated at the interface. Namely, a mechanism of the modulation of the effective work function φeff achieved by the segregation of impurities is different from the modulation of the effective work function φeff accomplished by the orientation of the germanide layer.

The modulation of φeff achieved by impurity segregation provides one advantage, and the modulation of φeff achieved by layer orientation provides another advantage. Hence, if both the impurity segregation and the layer orientation are performed, the effective work function φeff can be more modulated over the ranges illustrated in FIG. 3.

In the first embodiment shown in FIG. 1, the gate electrode is made of (102)-oriented TaGa₂, no matter whichever conductivity type of the device. Therefore, the embodiment can provide a C-MOS device having transistors that have a threshold value appropriate for LSTP transistors.

FIG. 6 is a sectional view schematically depicting the structure of a modification of the first embodiment. The modification is identical in basic structure to the first embodiment. It differs only in the material of the gate electrodes 213 and 313 of the n-type MOS and p-type MOS transistors, respectively. More precisely, the material, i.e., Ta germanide, contains nitrogen (N).

Nitrogen greatly differs from Ta in terms of electrical negativity. It therefore firmly combines with Ta, improving the thermal stability of Ta germanide. Any electrode made of N-containing Ta germanide can maintain its stable structure even after it has been heat-treated at about 1050° C. The electrode can therefore be formed by the same method as polycrystalline Si electrodes are made at present. In other words, the conventional method of activating the source and the drain after forming the gate electrode can be employed without any modification. Since the crystal grains of the electrode become smaller if nitrogen is added to Ta germanide, the effective work function φeff of Ta germanide is more uniform per unit area, despite the influence of the surface condition of each crystal grain. This renders it easier to control the threshold value of the transistors. Nonetheless, the addition of nitrogen makes the electrode amorphous, inevitably increasing the electrical resistance of the electrode. In view of this, it is desirable that nitrogen added be 50% or less. Here, the percentage [%] indicating the composition ratio means atomic percentage [atom %]. The addition of nitrogen achieves the same advantage in the other embodiments and the modifications thereof, which will be described hereinafter, though not discussed in conjunction with the other embodiments and the modifications thereof.

FIG. 7 is a sectional view schematically depicting the structure of another modification of the first embodiment. This modification is identical to the first embodiment (FIG. 1), except that a p-type Ge substrate 110 is used in place of the p-type Si substrate 10. As FIG. 7 shows, a p-type impurity region (p-type well) 211 and an n-type impurity region (n-type well) 311 are provided in the surface of the p-type Ge substrate 110. The regions 211 and 311 are spaced apart by an element-isolating film 111. As in the embodiment of FIG. 1, an n-type MOS transistor and a p-type MOS transistor are formed, which has gate electrodes 203 and 303 made of Ta germanide, respectively. The n-type MOS transistor and the p-type MOS transistor constitute a C-MOS device. Note that the element-isolating film 111 is made of GeON.

In the modification of FIG. 7, the heat treatment for making the transistors can be performed at a temperature for activating Ge (as low as about 500° C.). This heat treatment has good process-compatibility with Ta germanide that is the material of the gate electrodes. The method of manufacturing the device of FIG. 7 can therefore be simpler than the method of manufacturing the device illustrated in FIG. 1.

In the first embodiment, the contact provided on the diffusion layer at the source-drain region of each transistor is made of Ni silicide. Instead, the contact may be made of silicide of V, Cr, Mn, Y, Mo, Ru, Rh, Hf, Ta, W, Ir, Co, Ti, Er, Pt, Pd, Zr, Gd, Dy, Ho, Er or the like, which exhibits metal properties. In the other embodiments of this invention, which will be described later, Ni silicide is used as the material of contacts. Nonetheless, the contacts can of course be made of any other Ni silicide, unless otherwise specified. The contacts may be made of any metal that provide an appropriate resistivity and an appropriate junction depth that are required in the technology generation of the device.

In the first embodiment, the gate insulating films 202 and 302 are Si oxide films. Si oxide films can be replaced by insulating films (high-permittivity insulating films) that have higher permittivity than Si oxide film. More specifically, films of Si₃H₄, Al₂O₃, Ta₂O₅, TiO₂, La₂O₅, CeO₂, ZrO₂, HfO₂, SrTiO₃, Pr₂O₃ or the like. Materials such as Zr silicate and Hf silicates, each being an Si oxide containing metal ions, can be used as materials of gate insulating films 202 and 302. Further, a combination of these materials is useful as material of gate insulating films 202 and 302. One material may be selected from these choices and used, as needed in the transistors of various generations. In the embodiments that will be described later, too, Si oxide films are used as gate insulating films. Nonetheless, they can of course be replaced by high-permittivity insulating films, unless otherwise specified.

In the first embodiment, the gate electrodes are made of Ta germanide. This facilitates the manufacture of devices and provides an effective work function (φeff) required in the devices. Further, the addition of nitrogen to Ta germanide enhances the thermal stability of Ta germanide and renders the crystal grains smaller to increase the uniformity of effective work function (φeff). This can help to improve the reliability and performance of the device elements.

In the embodiments that will be described below are all C-MOS devices in which an n-type MOS transistor and a p-type MOS transistor operate complementary to each other. Nevertheless, these embodiments may not be C-MOS devices. Even in this case, the thermal stability of Ta germanide can enhance the performance and reliability of the non-CMOS devices.

### Second Embodiment

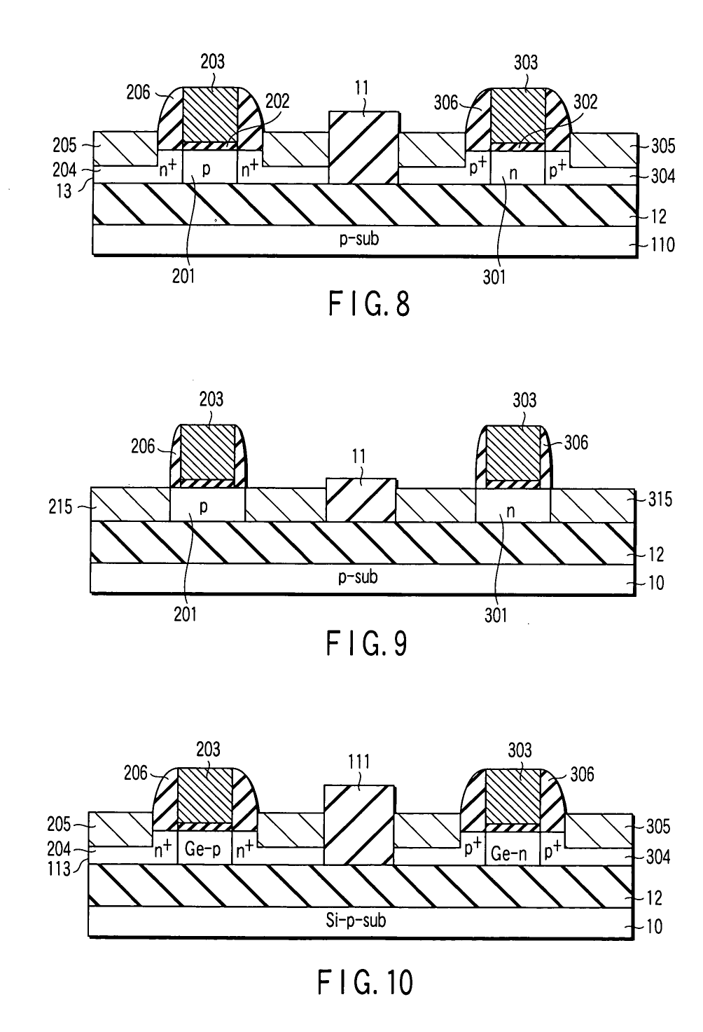

FIG. 8 is a sectional view schematically showing the structure of a MIS-type semiconductor device according to the second embodiment of the invention. The components identical to those shown in FIG. 1 are designated at the same reference numerals and will not be described in detail.

In the second embodiment, an Si oxide film (buried insulating film) 12 is formed on a p-type Si substrate 10. A single-crystal Si layer 13, which will be the active regions of MOS transistors, is formed on the Si oxide film 12. The film 12 and the Si layer 13 constitute a silicon-on-insulator (SOI) substrate. Preferably, the single-crystal Si layer 13, which will be active regions, are 5 to 10 nm thick. On the SOI substrate, an n-type MOS transistor and a p-type MOS transistor are formed. These MOS transistors have a gate electrode 203 and a gate electrode 303, respectively. The gate electrodes 203 and 303 are made of Ta germanide oriented in the (102) direction, as in the device shown in FIG. 1. The MOS transistors constitute a C-MOS device (i.e., SOI device).

In the second embodiment, all channel regions are depleted. Thus, the transistors are so-called fully-depleted SOI-MOS transistors. In any fully-depleted MOS device, the channel region has a low impurity concentration. It is therefore difficult to control the threshold value of the device by changing the impurity concentration of the channel region. To make matters worse, the gate electrode, which is made polycrystalline Si, provides but a negative threshold value, and the threshold voltage of the element cannot be controlled at all. Hence, it is more necessary to adjust the threshold value by changing the effective work function φeff of the poly-Si gate electrode than in any transistor (bulk device) that is formed on the ordinary Si substrate.

The gate electrode that a completely-depleted device requires has an effective work function φeff of 4.4 to 4.6 eV if the device is an nMOS device, and an effective work function φeff of 4.6 to 4.8 eV if the device is a pMOS device. The gate electrode of any LOP device needs to have an effective work function φeff of 4.5 to 4.7 eV, whether the LOP device is an nMOS one or a pMOS one. The gate electrode of any LSTP device must have an effective work function φeff of 4.7 to 4.9 eV if it is an nMOS device, and an effective work function φeff of 4.3 to 4.5 eV if it is a pMOS device.

The gate electrodes 203 and 303 shown in FIG. 8 have a threshold voltage required in SOI devices for LOP transistors. In manufacturing the device having a SOI substrate, the process of forming C-MOS elements of TaGaₓ (0<x<3) can be simplified as much as in manufacturing the bulk device.

FIG. 9 is a sectional view schematically depicting the structure of a modification of the second embodiment. In the modification, the shape of the gate electrodes shown in FIG. 8 is applied to Schottky MOS transistors. A Schottky transistor has a metal layer that is equivalent to the source-drain region. As FIG. 9 shows, metal layers 215 and 315 replace the n-type, high-concentration impurity region 204 and the p-type, high-concentration impurity region 304, respectively.

In nMOS transistors, the metal layers may be made of rare earth metals, a representative example of which is Er, or its silicides thereof because rare earth metals and its silicides thereof have a low Schottky barrier to electrons. In pMOS transistors, the metal layers may be made of silicides of precious metals, such as Pt, because silicides of precious metals have a low Schottky barrier to holes. The snowplowing phenomenon occurring during the reaction of silicide may be utilized to segregate P, As or B in high concentration at the metal/Si interface, thus forming a segregated Schottky structure. This structure effectively reduces the height of the Schottky barrier. It suffices to use the source-drain region and the contact structure, which are required in the generation of the device.

The gate electrodes are identical in structure to those of the first embodiment. The advantages they achieve are the same as in the first embodiment. The any other elements of the transistors may have structures that are optimal in view of the use of the device and the technology generation thereof, provided that the structures remain within the scope of the second embodiment.

The modification of FIG. 9 has a SOI structure to suppress the leakage current at the junction between the substrate and the source-drain region. Needless to say, the device shape can be applied to completely-depleted transistors, represented by a SOI transistor, and to three-dimensional devices represented by a FiN-FET.

FIG. 10 is a sectional view schematically depicting the structure of another modification of the second embodiment. This modification has a germanium-on-insulator (GOI) substrate, instead of an SOI substrate. The electrode structure of the first embodiment is provided on the GOI substrate.

To be more specific, an Si oxide film (buried insulating film) 12 is formed on a p-type Si substrate 10. A single-crystal Ge layer 113, which will be the active regions of MOS transistors, is formed on the Si oxide film 12. The film 12 and the Si layer 113 constitute a GOI structure. Preferably, the single-crystal Ge layer 113, which will be active regions, are 5 to 10 nm thick. On the GOI substrate, an n-type MOS transistor and a p-type MOS transistor are formed. These MOS transistors have a gate electrode 203 and a gate electrode 303, respectively. The gate electrodes 203 and 303 are made of Ta germanide oriented in the (102) direction, as in the device shown in FIG. 1. The MOS transistors constitute a C-MOS device (i.e., GOI device). Note that the element-isolating film 111 is made of GeON.

In the modification of FIG. 10, the heat treatment for making the transistors can be performed at a temperature for activating Ge (as low as about 500° C.). This heat treatment has good process-compatibility with Ta germanide that is the material of the gate electrodes. The method of manufacturing the device of FIG. 10 can therefore be simpler than the method of manufacturing the device that is shown in FIG. 8.

### Third Embodiment

FIG. 11 is a sectional view schematically showing the structure of a MIS-type semiconductor device according to a third embodiment of the present invention. The components identical to those shown in FIG. 1 are designated at the same reference numerals and will not be described in detail.

The third embodiment differs from the first embodiment, only in the structure of the gate electrodes. In any other structural respects, the embodiment is the same as the first embodiment.

As in the first embodiment (FIG. 1), a p-type well 201 and an n-type well 301 are provided in the surface of a p-type Si substrate 10. A gate insulating film 202 is formed on a part of the p-type well 201. Similarly, a gate insulating film 302 is formed on a part of the n-type well 301.

A gate electrode 223 is formed on the gate insulating film 202, and a gate electrode 323 is formed on the gate insulating film 302. The gate electrodes 223 and 323 have a double-layer structure composed of a lower layer and an upper layer. The lower layers 223a and 323a, which contact the gate insulating film 202 and 302, respectively, are made of Ta germanocilicide, Ta(SiGe) or Ta germanide. The ratio of Ge contained in Ta germosilicide or Ta germanide to Si is 80% or more. The upper layers 223b and 323b are made of Ta silicide or Ta germanosilicide in which the ratio of Ge to Si is 50% or less.

In the third embodiment, the gate electrode layers 223a 323a, each forming an interface with the gate insulating film, are made of either Ta germanosilicide, Ta(SiGe) (Ge>80%) or Ta germanide, TaGe2, which is oriented in the (102) direction. The advantage that the gate electrode layers 223a 323a impart to the device is similar to the advantage achieved in the first embodiment. The device according to the third embodiment is optimal structure for an LSTP transistor. Any TaGa₂ layer containing about 50% of Ge and formed at a high temperature of 600° C. or more exhibits little orientation. This renders it possible to modulate the effective work function φeff of TaSi2 from 4.2 eV to 5.0 eV, thanks to the Ge composition. The advantage explained in conjunction with the first embodiment is added, whereby the effective work function φeff is modulated over a broader range. Hence, the third embodiment can be applied to more types of devices and can broaden the range of threshold voltage for these devices.

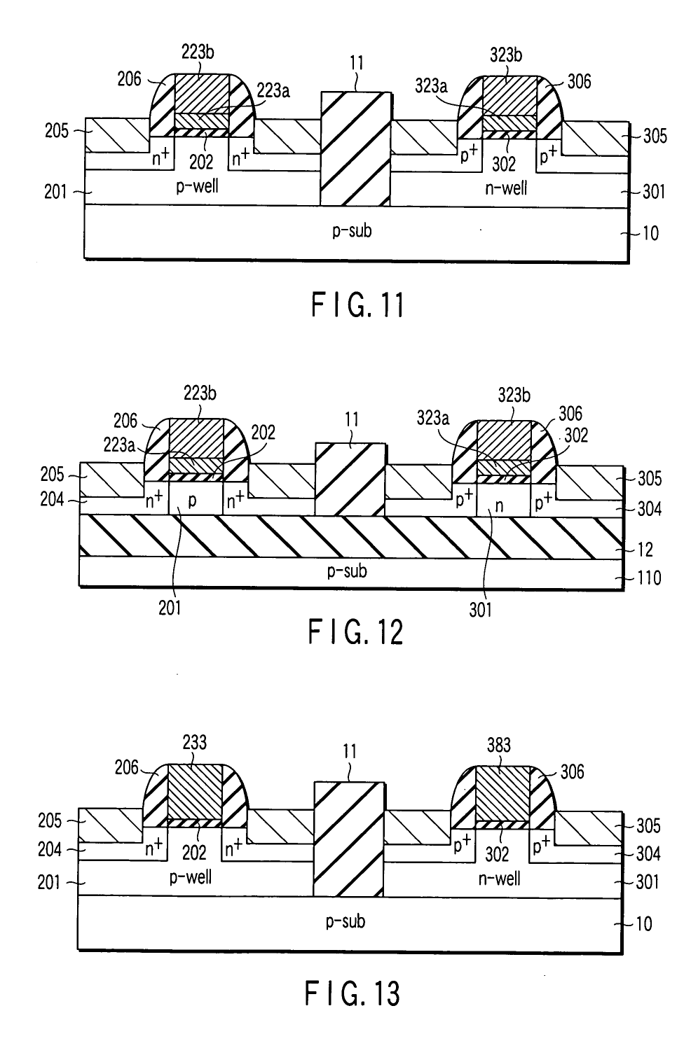

FIG. 12 is a sectional view schematically showing the structure of a modification of the third embodiment. The modification is a SOI device that has gate electrodes of gate electrodes according to the third embodiment. The modification achieves the same advantage as the third embodiment. Its device structure is appropriate to LOP transistors.

### Fourth Embodiment

FIG. 13 is a sectional view schematically showing the structure of a MIS-type semiconductor device, i.e., the fourth embodiment of the invention. The components identical to those shown in FIG. 1 are designated at the same reference numerals and will not be described in detail.

The fourth embodiment differs from the first embodiment, only in the material of the gate electrodes. In any other respects, the embodiment is the same as the first embodiment.

The gate electrode 233 provided on the p-type well 201 is made of Ta silicide. By contrast, the gate electrode 383 provided on the n-type well 301 is made of Ta germanide that. The gate electrode 383 has been formed through heat treatment at 600° C. or more and exhibits no orientation.

In the fourth embodiment, the nMOS transistor and the pMOS transistor differ in the material of gate electrode. (The gate electrode of one transistor is made of Ta silicide, and that of the other transistor is made of Ta germanide.) In the embodiment, Ta silicide has effective work function φeff of 4.2 eV, and Ta germanide effective work function φeff of 5.1 eV. As has been specified in conjunction with the first embodiment, these effective work function φeff are required in HP devices.

Having the configuration of FIG. 13, the transistors according to the fourth embodiment are high-performance, high-reliability devices, like the devices according to the first embodiment. As in the first embodiment, impurities are introduced at the interface between the gate electrode and gate insulating film of each transistor. The effective work function φeff can be modulated over the ranges indicated by arrows in FIG. 3. Thus, the fourth embodiment can provide effective work functions φeff that are required in LOP devices, too.

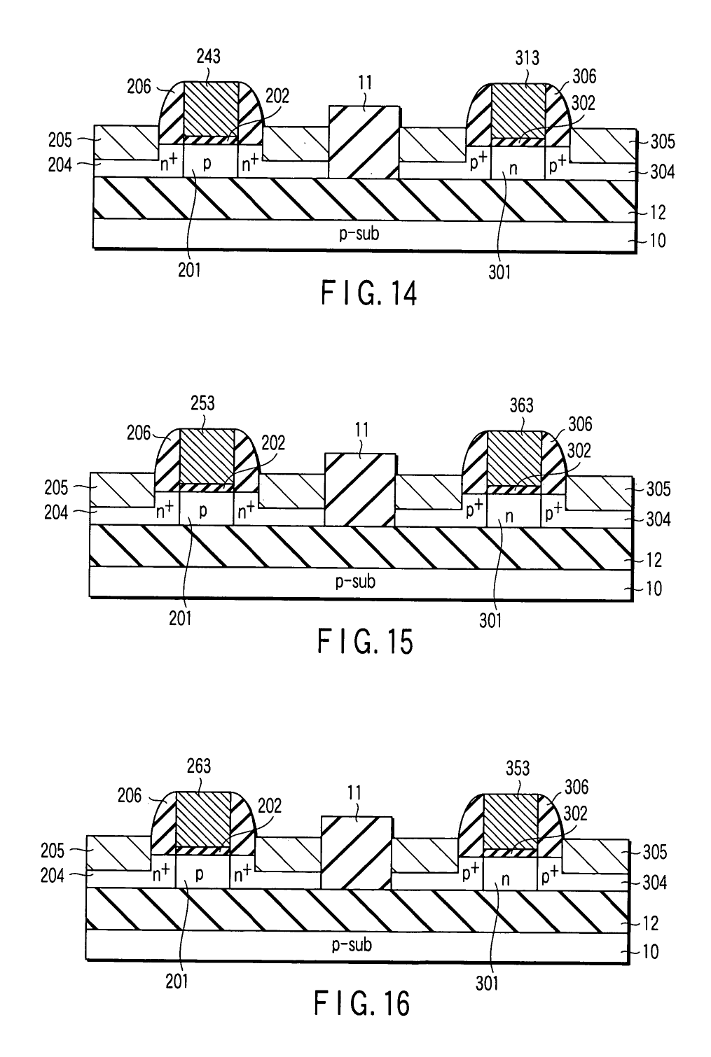

FIG. 14 is a sectional view schematically depicting the structure of a modification of the fourth embodiment. As in the structure of FIG. 13, the gate electrodes are made of Ta germanide or Ta silicide. The gate electrode of the device of at least conductivity type contains 1% or more of nitrogen. For example, the gate electrode 243 provided on the p-type well 201 is made of TaSiₓN_{y} and the gate electrode 313 provided on the n-type well 301 is made of TaGaₓN_{y} (0<y<0.5). The substrate is an SOI substrate. In the modification, the addition of nitrogen (N) renders the crystal grains smaller, increasing the uniformity of effective work function (φeff) per unit area, despite the influence of the surface condition of each crystal grain. This facilitates the control of the threshold values of both transistors. Further, the addition of nitrogen enhances the thermal resistance of the gate electrodes 243 and 313. The gate electrodes 243 and 313 can therefore be formed in the same way as polycrystalline silicon electrodes are formed at present. This ultimately reduces the development cost and manufacturing cost of the device.

FIG. 15 is a sectional view schematically illustrating the structure of another modification of the fourth embodiment. This modification is a SOI device to which the electrode structure of the fourth embodiment is applied and in which B is added. More precisely, boron (B) is added at the interface between the Ta silicide layer (one gate electrode) and one gate insulating film and at the interface between the Ta germanide layer (the other gate electrode) and the other gate insulating film. For example, the gate electrode 253 provided on the p-type well 201 is made of B-containing Ta silicide, and the gate electrode 363 provided on the n-type well 301 is made of B-containing Ta germanide. The gate electrodes 253 and 363 have an effective work function φeff of 4.4 eV and an effective work function φeff of 4.8 eV, respectively. The resultant transistors can have so low a threshold value that they can operate as high-speed (HP) transistors.

FIG. 16 is a sectional view schematically illustrating the structure of still another modification of the fourth embodiment. This modification differs from the modification of FIG. 15, in that the gate electrodes replace each other, in terms of the conductivity type (i.e., p type or n type). That is, the gate electrode 263 provided on the n-type well 301 is made of B-containing Ta germanide, while the gate electrode 353 provided on the n-type well 301 is made of B-containing Ta silicide. Only the replacement between the gate electrodes can provide LSTP transistors. If the substrate is of the SOI structure, too, the addition of nitrogen (N) achieves the same advantage as attained by adding nitrogen (N). The three modifications of the fourth embodiment can be combined in any possible way, to provide semiconductor devices.

### Fifth Embodiment

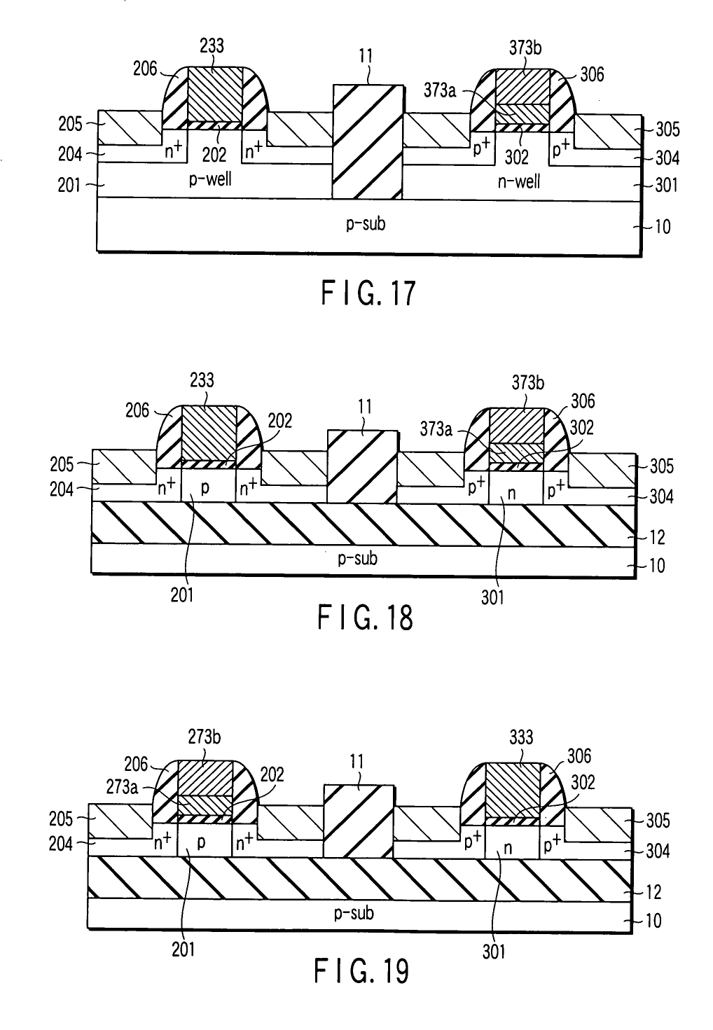

FIG. 17 is a sectional view schematically showing the structure of a MIS-type semiconductor device according to a fifth embodiment of this invention. The components identical to those shown in FIG. 1 are designated at the same reference numerals and will not be described in detail.

The fifth embodiment differs from the first embodiment (FIG. 1) in the structure of either gate electrode. In any other respects, the embodiment is the same as the first embodiment.

As FIG. 17 depicts, the gate electrode 233 provided on the p-type well 201 is made of Ta silicide. On the other hand, the gate electrode 373 provided on the n-type well 301 is a double-layer structure, composed of a lower layer 373a and an upper layer 373b. The lower layer 373a that contacts the gate insulating 302 is made of Ta germosilicide, Ta(SiGe), or Ta germanide. The lower layer 373a contains 80% or more of Ge, with respect to Si. The upper layer 373b is made of either Ta silicide or Ta germanosilicide that contains 50% or less of Ge, with respect to Si.

In the fifth embodiment, that part of the gate electrode which contacts the gate insulating film in the pMOS transistor is made of Ta germanide or germanosilicide (Ge>80%), and that part of the gate electrode which contacts the gate insulating film in the nMOS transistor is made of Ta silicide. In this respect, the fifth embodiment is virtually identical to the fourth embodiment illustrated in FIG. 13. Hence, the fifth embodiment can be applied to any device in which each transistor requires the same threshold voltage as the transistors of the structure shown in FIG. 13. Therefore, the fifth embodiment achieves the same advantage as the fourth embodiment. As will be described in detail in conjunction with the methods of manufacturing other embodiments of the invention, the fifth embodiment can be more easily manufactured than the fourth embodiment (FIG. 13). The fifth embodiment can therefore be developed at lower cost, and it is more desirable than the fourth embodiment in terms of structure.

FIGS. 18 and 19 are sectional views schematically depicting two modifications of the fifth embodiment, respectively. FIG. 18 shows a modification that has a SOI substrate. The structure of FIG. 18 can provide transistors that have such a threshold voltage as to operate high-speed (HP) transistors. FIG. 19 shows a modification identical to the modification of FIG. 18, except that the gate electrodes replace each other in terms of conductivity type (i.e., p type and n type). As FIG. 19 shows, the gate electrode 273 provided on the p-type well 201 is a double-layer structure composed of a lower layer 273a and an upper layer 273b. The lower layer 273a is made of Ta germanosilicide (Ge≧80%) or Ta germanide. The upper layer 273b is made of Ta silicide or germanosilicide (Ge≦50%). The gate electrode 333 provided on the n-type well 301 is made of Ta silicide.

If LSTP transistors are formed in a SOI device as in this case, their gate electrodes need to have such a work function as the gate electrode of the ordinary p-type MIS transistor should have. Thus, LSTP transistors can be provided, merely by replacing the gate electrodes of two transistors in terms of conductivity type (p, n). The modifications of FIGS. 18 and 19 of the fifth embodiment can operate as reliably and fast as the first embodiment.

### Sixth Embodiment

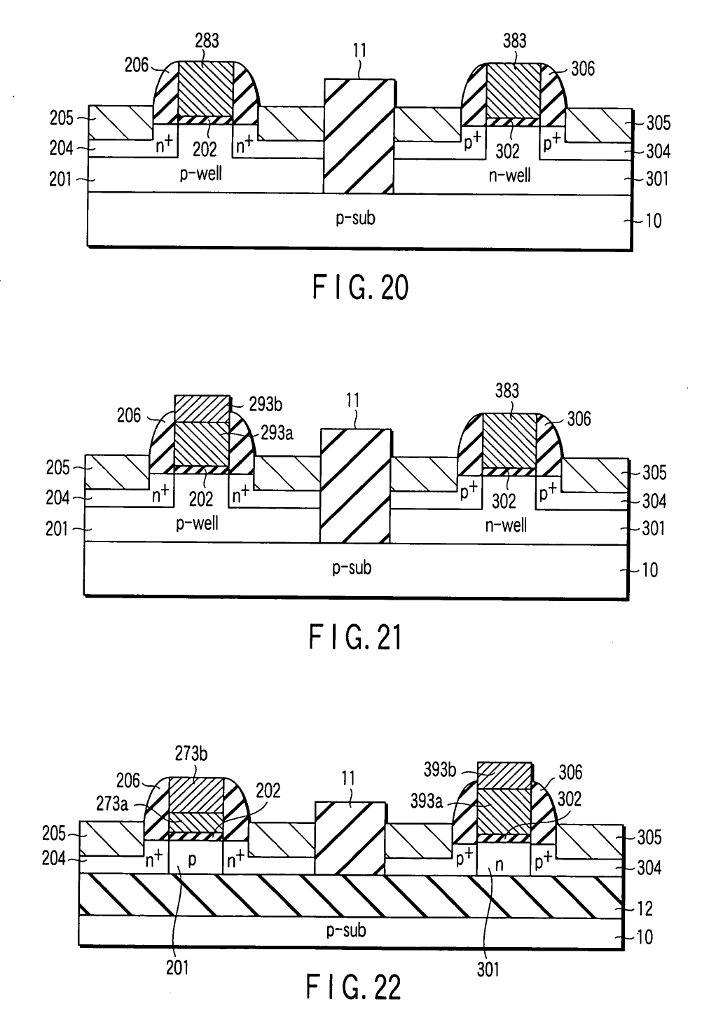

FIG. 20 is a sectional view schematically showing the structure of a MIS-type semiconductor device according to the sixth embodiment of the present invention. The components identical to those shown in FIG. 1 are designated at the same reference numerals and will not be described in detail.

The sixth embodiment differs from the first (FIG. 1), only in the material of the gate electrodes. In any other respects, it is the same as the first embodiment.

The gate electrode 283 provided on the p-type well 201 is made of Al. The gate electrode 383 provided on the n-type well 301 is made of Ta germanide, formed through heat treatment carried out at 600° C. or more.

Aluminum used as material of the gate electrode 283 in the sixth embodiment has an effective work function φeff ranging from 4.1 to 4.3 eV. The effective work function φeff of the gate electrode 283 is therefore desirable for the gate electrode of any HP transistor. The resistivity of Al is 2.65 μΩcm, which is much lower than that of Ta silicide (>10 μΩcm). This renders it possible to manufacture C-MOS devices that operate still faster than the first embodiment.

Al electrodes are formed by depositing Al on a polycrystalline Si layer and performing heat treatment at the same temperature as in forming a TaGeₓ layer. An Al electrode can be provided, utilizing the effect of replacing Al with Si. Thus, two gate electrodes can be formed at the same time for the pMOS transistor and the nMOS transistor, respectively, if the gate electrode of the pMOS transistor is formed of Ta germanide. This facilitates the manufacturing process. In addition, a device as reliable as the first embodiment can be provided since Al electrodes can be formed through heat treatment performed at temperature (about 600° C.) lower than the temperature (about 1000° C.) at which polycrystalline Si electrodes are formed by the existing method.

Al may be replaced by TaB. TaB has an effective work function φeff of 4.3 to 4.4 eV, which is closer to the center of Si forbidden band than aluminum (Al) as shown in FIG. 3. TaB can therefore be used in nMIS transistors that are equivalent to the LSTP bulk devices. In an SOI device, TaB can be used in HP nMOS transistors and in LSTP pMOS transistors. Having a melting point of approximately 3000° C., TaB can fully withstand the heat treatment that activates the source-drain regions of the transistors. The conventional method, in which gates are formed prior to activation of S/D dopant, can be employed.

FIGS. 21 and 22 are sectional views schematically depicting the structure of two modifications of the sixth embodiment, respectively. FIG. 21 shows a C-MOS device in which the gate electrode 283 of the nMOS transistor shown in FIG. 20 is replaced by a double-layer structure that is composed of an Al layer 293a and an Si layer 293b. If the Si layer 293b is left unremoved after forming the Al layer 293a, this modification will be identical to the sixth embodiment (FIG. 20). The modification of FIG. 21 has the same characteristic and the same advantage as the sixth embodiment of FIG. 20.

The modification illustrated in FIG. 22 is has a SOI substrate. In this modification, the pMOS transistor has a gate electrode 393 of the same structure as the nMOS transistor shown in FIG. 21, and the nMOS-transistor has a gate electrode 273 of the same structure as the nMOS transistor shown in FIG. 19.

More specifically, the gate electrode 273 of the nMOS transistor is a double-layer structure composed of a lower layer 273a and an upper layer 273b. The lower layer 273a is made of Ta germanosilicide, Ta(SiGe) or Ta germanide and contains 80% or more of Ge with respect to Si. The upper layer 273b is made of either Ta silicide or Ta germanosilicide that contains less or equal to 50% with respect to Si. The gate electrode 393 of the pMOS transistor is a double-layer structure, too. This double-layer structure is composed of a lower layer 393a and an upper layer 393b. The lower layer 293a that contacts the gate insulating film 302 is made of Al, and the upper layer 393b is made of SiGe.

To form an Al layer on a gate electrode, the gate electrode may be made polycrystalline Ge or SiGe, not polycrystalline Si, and an Al layer is then formed on the gate electrode of polycrystalline Ge or SiGe. Thus, polycrystalline Ge or polycrystalline SiGe replaces Al. In the pMOS transistor, the gate electrode may be a single layer made of TaGeₓ s in the modification of FIG. 21, thereby achieve the same advantage as the modification of FIG. 21.

In the modification shown in FIG. 22, the dummy electrodes of Ge or SiGe can be formed for both the pMOS transistor and the nMOS transistor before forming their gate electrodes. In this case, Ge can smoothly replace Al. This facilitates the process of manufacturing the device according to the sixth embodiment illustrated in FIG. 20.

### Seventh Embodiment

FIGS. 23A to 23D are sectional views illustrating a method of manufacturing the MIS-type semiconductor device shown in FIG. 8.

First, as FIG. 23A shows, an SOI substrate is prepared. The SOI substrate comprises a p-type Si substrate 10, an Si oxide film (buried insulating film) 12 and a single-crystal Si layer 13, which are bonded together. The element isolation can be accomplished by local oxidation, shallow-trench process, or by forming a mesa structure. Thereafter, ions are implanted into the SOI top layer, forming a p-type impurity region (p-type well) 210 and an n-type impurity region (n-type well) 301. Then, Si oxide films 402 are formed on the wells 201 and 301, respectively. CVD is then carried out, depositing a polycrystalline Ge film 401 on the entire surface of the SOI substrate.

As shown in FIG. 23B, patterning is performed by means of lithography. The structure is then subjected to anisotropic etching, forming gate parts. More precisely, the polycrystalline Ge film 401 and the Si oxide films 402 are processed into electrode patterns. As a result, that part of one oxide film 402 which lies on the p-type well 201 forms a gate insulating film 202, and that part of the other oxide film 402 which lies on the n-type well 301 forms a gate insulating film 302.

As FIG. 23C shows, arsenic (As) and boron (B) are ion-implanted, thereby forming a source-drain region 204 for an nMOS transistor and a source-drain region 304 for a pMOS transistor. During the heat treatment performed to activate the source-drain regions 204 and 304, a cap layer made of W protects Ge in the gates. Source-drain diffusion layers can be formed at lower temperatures, by means of selective epitaxial growth, which can suppress the short-channel effect. Impurities may be introduced during the selective epitaxial growth.

Subsequently, sidewall insulating films 206 and 306 are formed, insulating the gate electrodes and the source-drain regions. Ni silicide layers 205 and 305 are formed as contact layers for the source-drain regions 204 and 304, respectively. CVD is performed, depositing an Si oxide film 403 that is thicker than the gate electrodes. Chemical mechanical polishing (CMP) is carried out, exposing the tops of the gate electrodes. Thereafter, a Ta film 405 is formed by sputtering. The Ta film 405 is thick enough to change the Ge layers 401 may be chanced to germanide layers. A W film 407, which is a protection film for preventing oxidation, is formed on the W film 407 by means of sputtering. It is desired that the Ta film 405 be about half as thick as the Ge electrodes are high.

Heat treatment is then carried out at 500° C. or less. Those parts of the Ta film 405 and W film 407, which remain not reacted, are removed. A structure is thereby obtained, which has gate electrodes 203 and 303 made of TaGe₂ and oriented in the (102) direction.

In this method, the heat treatment for forming gate electrodes is performed at low temperatures, and the formation energy of Ta₂O₅, oxide of Ta, is smaller in absolute value than the formation energy of Si oxide film or high-permittivity film containing Hf, La or Zr. Hence, the insulating film is not eroded. A high-reliability device can therefore provided. The diffusion coefficient of Ta in SiO2 is smaller, by about two orders of magnitude, than the diffusion coefficient of Ni, a metal element existing in gate electrodes available at present. Thus, it is possible to suppress diffusion of atoms into the channels, not degrading the electrical characteristics of the device.

As specified above, the SOI substrate used in this embodiment is made by bonding various layers together. Nonetheless, the SOI substrate may be replaced by a SOI substrate prepared by separation by implanted oxygen (SIMOX) or a SOI substrate prepared by epitaxial layer transfer. The other embodiments to be described below use a SOI substrate made by bonding layers. Nevertheless, any other type of a SOI substrate can be used in the other embodiments, unless otherwise remarked.

### Eighth Embodiment

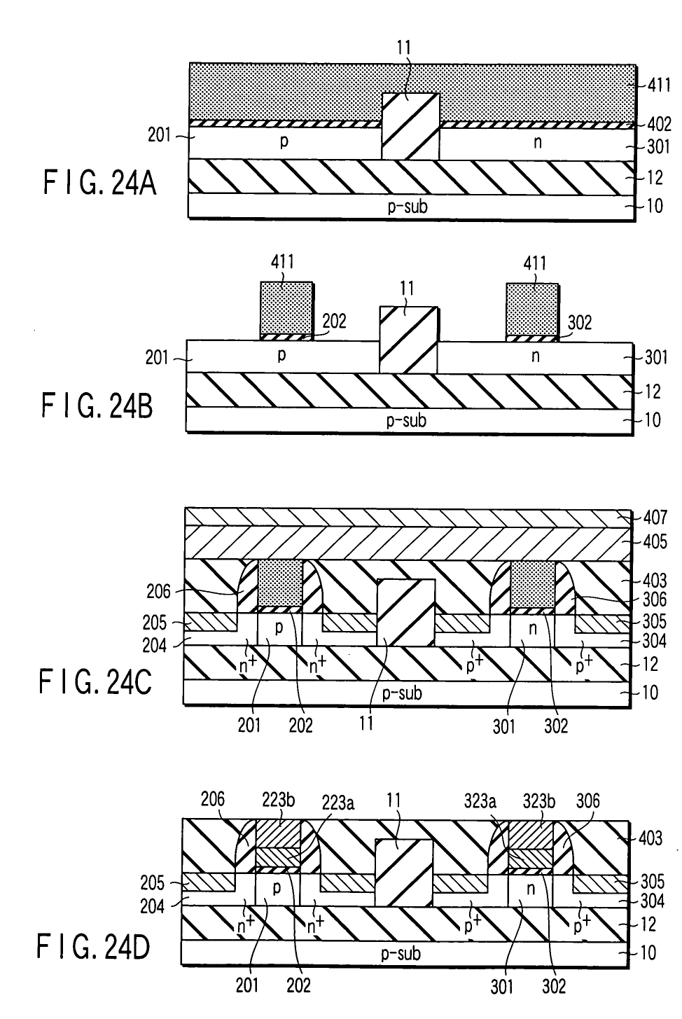

FIGS. 24A to 24D are sectional views showing a method of manufacturing the MIS-type semiconductor device shown in FIG. 12.

An SOI substrate is prepared by the same method as described the reference to FIG. 23A. A p-type well 201, an n-type well 301, an element-isolating film 11, and an Si oxide film 402 to be used as gate insulating film are formed in and on the SOI substrate. Thereafter, as shown in FIG. 24A, CVD is performed, depositing a polycrystalline SiGe film 411 on the entire surface of the substrate. It is desired that the SiGe film 411 contain 60% or less of Ge.

Next, as FIG. 24B shows, patterning is performed by means of lithography. The structure is then subjected to anisotropic etching, forming gate parts. More precisely, the polycrystalline SiGe film 411 and the oxide films 402 are processed into gate electrode patterns.

As FIG. 24C shows, arsenic is ion-implanted, thereby forming a source-drain region 204 for an nMOS transistor, and boron is ion-implanted, forming a source-drain region 304 for a pMOS transistor. During the heat treatment performed to activate the source-drain regions 204 and 304, a cap layer made of W protects SiGe in the gates. If the polycrystalline SiGe layer 411 contains Ge in a sufficient amount, or source-drain regions should be made of SiGe, the W protection film need not be formed. This is because the melting point of Ge is lower than that of Si and the impurities can be activated in the SiGe layer 411 at a lower temperature than in an Si layer. Subsequently, sidewall insulating films 206 and 306 and Ni silicide layers 205 and 305 are formed in the same way as is illustrated in FIG. 23C. An Si oxide film 403 is deposited. CMP is carried out, exposing the tops of the gate electrodes. Thereafter, a Ta film 405 is formed by sputtering.

Heat treatment is then carried out at 500° C. or less. Those parts of the Ta film 405 and W film 407, which remain not reacted, are removed. During this heat treatment, Ta readily reacts with Si in SiGe because TaSiₓ is more stable than TaGeₓ. Ge not reacted is expelled to the reaction interface. The content of Ge at the interface with the gate insulating film is higher than at the time of forming the SiGe film. TaSiGe (Ge>80%) or Ta germanide is formed in the vicinity of the interface with the gate insulating film. Hence, the gate electrode is a double-layer structure composed of an upper layer and a lower layer. The upper layer is made of Ta silicide layer scarcely containing Ge, or Ta(SiGe) (Ge<50%). The lower layer is made of Ta(SiGe)ₓ containing 80% or more of Ge or TaGex. Thus, the method can provide a device that has the structure shown in FIG. 12.

### Ninth Embodiment

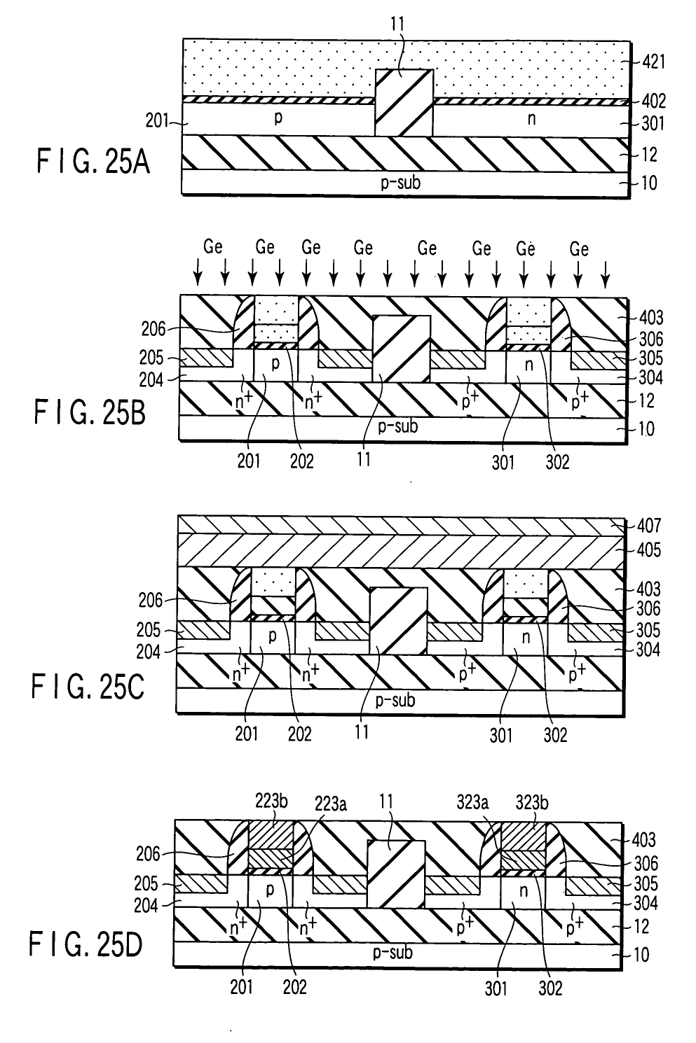

FIGS. 25A to 25D are sectional views illustrating a method of manufacturing the MIS-type semiconductor device of the structure shown in FIG. 12.

A p-type well 201, an n-type well 301, an element-isolating film 11 made of Si oxide, and an Si oxide film 402 used as gate insulating film are formed in and on a SOI substrate, by performing the same process as shown in FIG. 23A. Then, as FIG. 25A shows, CVD is carried out, depositing a polycrystalline Si film 421 on the entire surface of the SOI substrate.

As FIG. 25B shows, patterning is performed by means of lithography. The structure is then subjected to anisotropic etching, forming gate parts. That is, the polycrystalline SiGe film 421 and the oxide films 402 are processed into gate electrode patterns. Then, arsenic is ion-implanted, forming a source-drain region 204 for an nMOS transistor, and boron is ion-implanted, forming a source-drain region 304 for a pMOS transistor. Thereafter, sidewall insulating films 206 and 306 and Ni silicide layers 205 and 305 are formed in the same way as is illustrated in FIG. 23C. An Si oxide film 403 is deposited. The tops of the gate electrodes are then exposed.

In this condition, Ge is ion-implanted, thus introducing 30% or more of Ge into the upper parts of the gate electrodes. The upper parts of the gate parts made of polycrystalline Si change into polycrystalline SiGe layers.

Next, as FIG. 25C depicts, a Ta film 405 is formed on the entire surface of the substrate, and a W film 407 is formed on the Ta film 405 by sputtering.

Heat treatment is then carried out at 500° C. or less. Those parts of the Ta film 405 and W film 407, which remain not reacted, are removed. During this heat treatment, Ge is expelled to the reaction interface and reacted gradually as is illustrated in FIG. 24D. The content of Ge at the interface with the gate insulating film becomes higher than at the time of forming the SiGe film, increasing to 80% or more. Ta(SiGe)ₓ (Ge>80%) or TaGeₓ is formed in the vicinity of the interface with the gate insulating film. As a result, the gate electrode is a double-layer structure composed of an upper layer and a lower layer. The upper layer is made of Ta silicide layer that scarcely contains Ge. The lower layer is made of Ta(SiGe)ₓ containing 80% or more of Ge with respect to Si TaGeₓ, or of TaSiGex.

In this method, no W protection film is necessary at the time activating Ge in the gate electrodes, even if the source-drain regions are made of Si. The method of manufacturing the device is more simplified.

### Tenth Embodiment

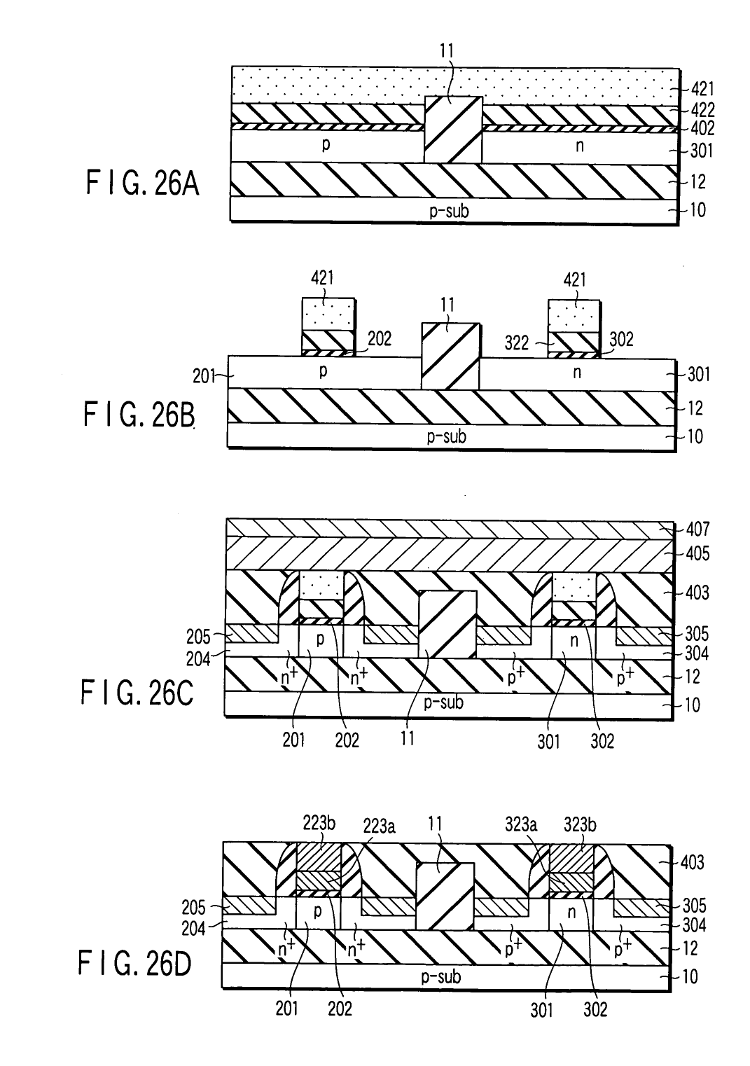

FIGS. 26A to 26D are sectional views showing a method of manufacturing the MIS-type semiconductor device illustrated in FIG. 12.

As FIG. 26A shows, a p-type well 201, an n-type well 301, an element-isolating film 11 made of Si oxide, and an Si oxide film 402 used as gate insulating film are formed in and on a SOI substrate, by performing the same process as shown in FIG. 23A. A Ge oxide film 422 is formed on the Si oxide film 402. Nitrogen may be introduced into the Ge oxide film 422. Then, CVD is performed, depositing a polycrystalline Si film 421 on the entire surface of the substrate.

As shown in FIG. 26B, patterning is performed by means of lithography. The structure is then subjected to anisotropic etching, forming gate parts. That is, the polycrystalline SiGe film 421, Ge oxide film 422 and the oxide films 402 are processed into gate electrode patterns, for the wells 201 and 301.

As FIG. 26C shows, arsenic is ion-implanted, forming a source-drain region 204 for an nMOS transistor and boron is ion-implanted, forming a source-drain region 304 for a pMOS transistor. Thereafter, sidewall insulating films 206 and 306 and Ni silicide layers 205 and 305 are formed in the same way as is illustrated in FIG. 23C. An Si oxide film 403 is deposited. The tops of the gate electrodes are then exposed. Subsequently, a Ta film 405 is formed on the entire surface of the substrate, and a W film 407 is formed on the Ta film 405 by sputtering.

Heat treatment is then carried out at 500° C. or less. Those parts of the Ta film 405 and W film 407, which remain not reacted, are removed as is illustrated in FIG. 26D. While said parts of the films 405 and 407 are being removed, the upper parts of the gates, which are made of Si, change to Ta silicide. Less stable than Ta germanide, the Ge oxide layer at interface with the gate insulating film forms TaGeₓ. At this time, oxygen in Ge oxide are taken into the lower gate insulating layer, forming Si oxide at the interface (upper interface) between the gate electrode and the gate insulating film and at the interface (lower interface) between the gate insulating film and the Si channel. As a result, the gate electrode becomes a double-layer structure composed of an upper layer and a lower layer. The upper layer is made of Ta silicide, and the lower layer is made of Ta germanide. A MIS-type semiconductor device of the structure shown in FIG. 12 can therefore be provided.

### Eleventh Embodiment

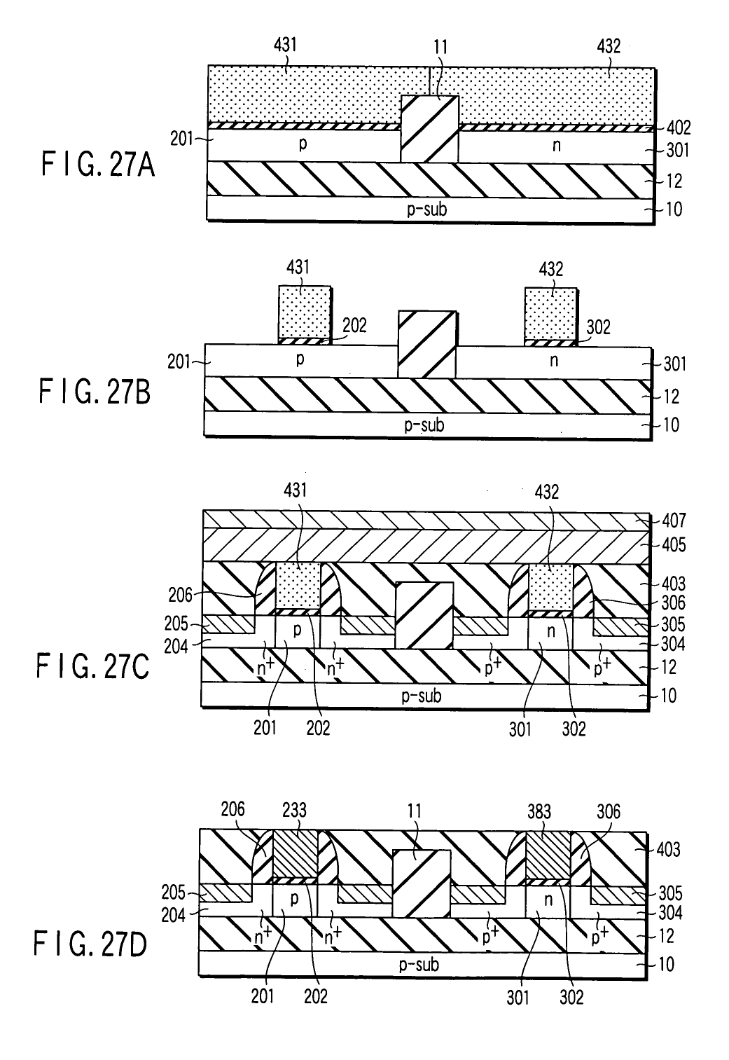

FIGS. 27A to 27D are sectional views showing a method of manufacturing a MIS-type semiconductor device shown in FIG. 13. Nonetheless, this device differs from the device of FIG. 13 in that the substrate is of the SOI structure.

First, as FIG. 27A shows, a p-type well 201, an n-type well 301, an element-isolating film 11 made of Si oxide, and an Si oxide film 402 used as gate insulating film are formed in and on a SOI substrate, by performing the same process as shown in FIG. 23A. Then, CVD and lithography are performed, forming a Si layer 431 on the p-type well 201 and a Ge layer 432 on the n-type well 301.

As shown in FIG. 27B, patterning is performed by means of lithography. The structure is then subjected to anisotropic etching, forming gate parts. That is, the Si layer 431 and oxide film 402 are processed into a gate electrode pattern for the n-type well 301, and the Ge layer 432 and oxide film 402 into a gate electrode pattern for the p-type well 301.

As FIG. 27C shows, arsenic is ion-implanted, forming a source-drain region 204 for an nMOS transistor, and boron is ion-implanted, forming a source-drain region 304 for a pMOS transistor. During the ion implantation, a W layer protects the upper part of the p-type MOS transistor region. Thereafter, sidewall insulating films 206 and 306 and Ni silicide layers 205 and 305 are formed. An Si oxide film 403 is deposited. The tops of the gate electrodes are then exposed. The Subsequently, a Ta film 405 is formed on the entire surface of the substrate, and a W film 407 is formed on the Ta film 405 by sputtering.

Heat treatment is then carried out at 500° C. or less. Those parts of the Ta film 405 and W film 407, which remain not reacted, are removed as is illustrated in FIG. 27D. Now that said parts of the films 405 and 407 have been removed, a gate electrode 233 of Ta silicide is formed on the nMOS transistor region, and a gate electrode 283 of Ta germanide is formed on the pMOS transistor region. As a result, the structure of FIG. 13 is obtained.

### Twelfth Embodiment

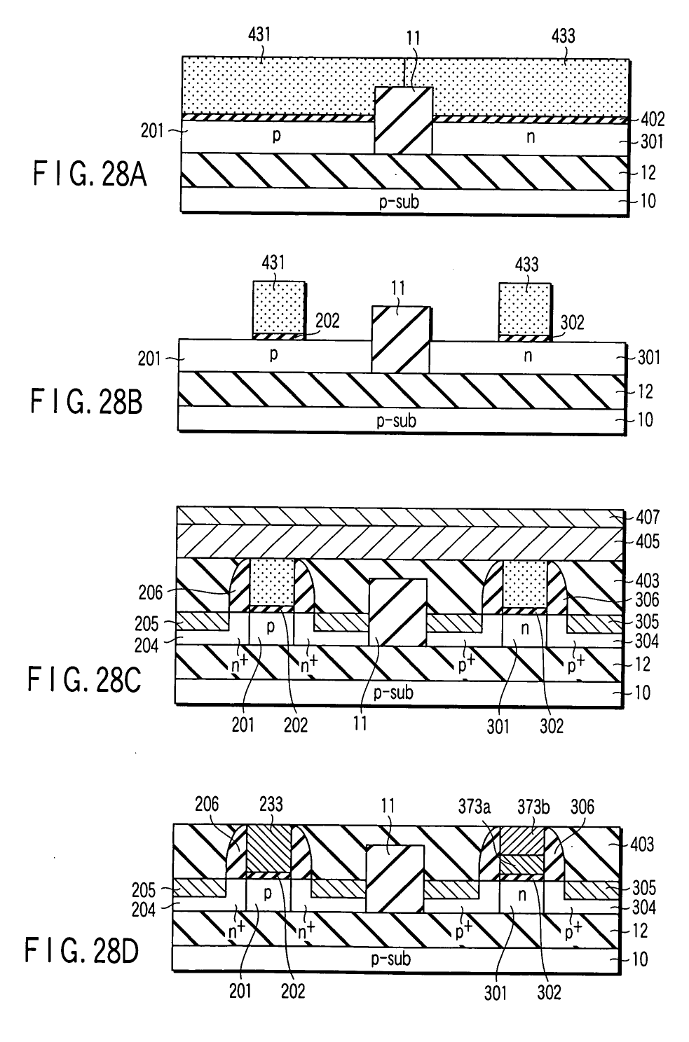

FIGS. 28A to 28D are sectional views illustrating a method of manufacturing the MIS-type semiconductor device shown in FIG. 18.

The steps shown in FIGS. 28A to 28C are essentially identical to those shown in FIG. 27A to 27C, except that a polycrystalline SiGe layer 433 is formed in place of the Ge layer 432.

The structure depicted in FIG. 28C is subjected to heat treatment at 500° C. or less. Then, those parts of the Ta film 405 and W film 407, which remain not reacted, are removed as shown in FIG. 28D. Now that said parts of the films 405 and 407 have been removed, a gate electrode 233 of Ta silicide is formed on the nMOS transistor region, and a gate electrode 373 of Ta germanide, i.e., a double-layer structure (layers 373a and 373b), is formed on the pMOS transistor region. As a result, the structure of FIG. 18 is provided.

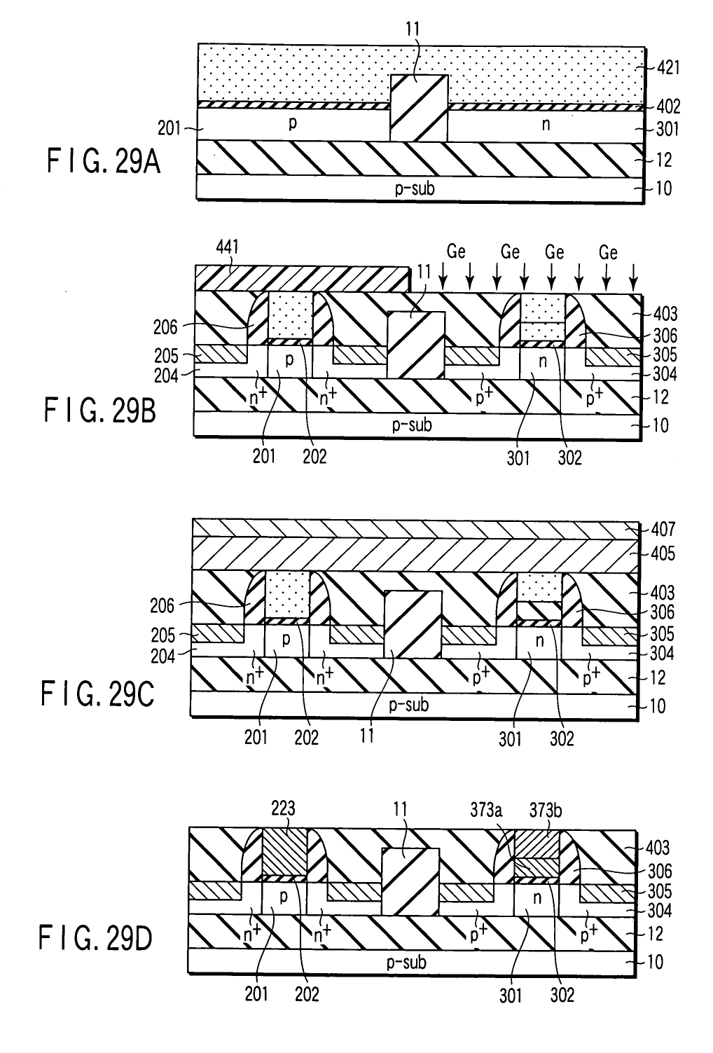

FIGS. 29A to 29D are sectional views showing another method of manufacturing the MIS-type semiconductor depicted in FIG. 18.

In this method, an Si layer 421 is formed on the entire surface of the structure as shown in FIG. 29A, not as is illustrated in FIG. 28A. As FIG. 29B shows, that part of the Si layer 421 which lie on the p-type well 201 is masked with a resist mask 441. Then, Ge ions are injected into that part of the Si layer 421 which lies on the n-type well 201. Thereafter, steps identical to the steps of FIGS. 28B and 28C are carried out. A structure of FIG. 18 is thereby obtained.

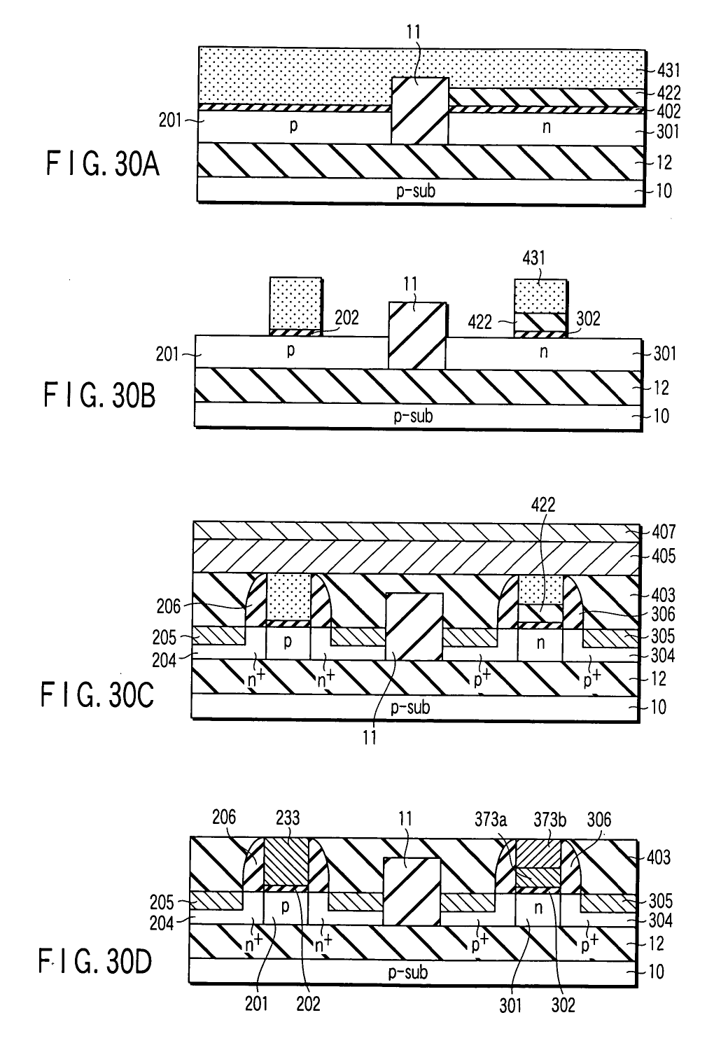

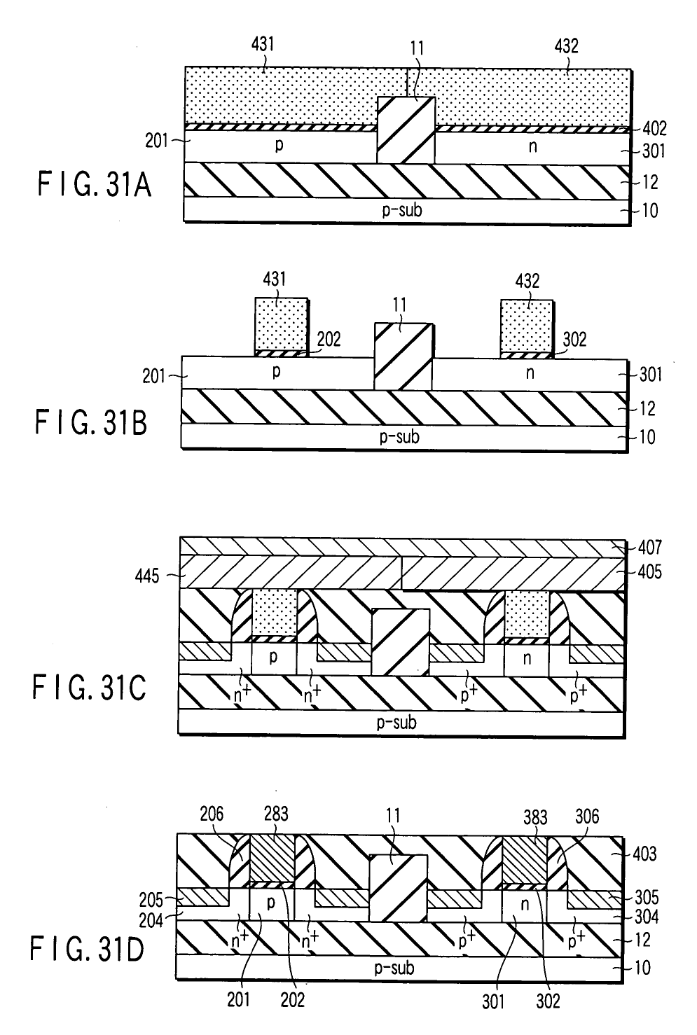

FIGS. 30A to 30D are sectional views showing still another method of manufacturing the MIS-type semiconductor illustrated in FIG. 18. In this method, a Ge oxide film 422 is formed between an Si layer 431 and an Si oxide film 402, both provided on the n-type well 301, as is illustrated in FIG. 30A. Thereafter, steps identical to the steps of FIGS. 28B and 28C are carried out. Thus, a structure of FIG. 18 is provided.

### Thirteenth Embodiment

FIGS. 31A to 31D are sectional views depicting a method of manufacturing the MIS-type semiconductor device depicted in FIG. 20.

As FIG. 31A shows, a p-type well 201, an n-type well 301, an element-isolating films 11 made of Si oxide, and an Si oxide film 402 used as gate insulating film are formed in and on a SOI substrate, by performing the same process as shown in FIG. 23A. A Ge oxide film 422 is formed on the Si oxide film 402. Then, CVD is performed, depositing a polycrystalline Si film 431 on the p-type well region 201, and a Ge layer 432 on the n-type well region 301.

Next, as shown in FIG. 31B, patterning is performed by means of lithography. The structure is then subjected to anisotropic etching, forming gate parts. As a result, a Si gate electrode is formed on the p-type well 201, and a Ge gate electrode is formed on the n-type well 301.

As FIG. 31C shows, arsenic is ion-implanted, forming a source-drain region 204 for an nMOS transistor, and boron is ion-implanted, forming a source-drain region 304 for a pMOS transistor. Thereafter, sidewall insulating films 206 and 306 and Ni silicide layers 205 and 305 are formed in the same way as is illustrated in FIG. 23C. An Si oxide film 403 is deposited. The tops of the gate electrodes are then exposed. Subsequently, an Al film 445 is formed on the p-type well region 201 by sputtering, and a Ta film 405 is formed on the n-type well region 301 by sputtering. The films 445 and 405 may have a thickness that is optimal for accomplishing reaction or replacement with the gate electrodes. For example, both the Ta film and the Al film are 30 to 50 nm thick if the gate electrodes have a height of 60 nm. A desired structure can then be provided. A W film 407 is formed on the films 405 and 445, preventing oxidation. A cap layer made of Ti or TiN may be formed on the Al film 445 in order to promote the reaction in the subsequent heat treatment.

Next, as FIG. 31D shows, heat treatment is carried out at 600° C. The upper (Al) and lower parts (Si) of the Si gate electrode provided on the p-type well region 201 are replaced by each other, forming an Al gate electrode 283 near the interface with the gate insulating film. Meanwhile, the Ge gate electrode 383 on the n-type well region 301 undergoes solid-phase reaction with Ta, forming Ta germanide. Metal layers not reacted and the upper Si layer, or the Ti silicide layer reacted with the Ti cap layer is removed by chemical etching. As a result, the structure of FIG. 20 is obtained. If the etchant used cannot dissolve Si or TiSi₂, only Ta and W, not reacted, will be removed. In this case, the structure of FIG. 21 is provided.

### Fourteenth Embodiment

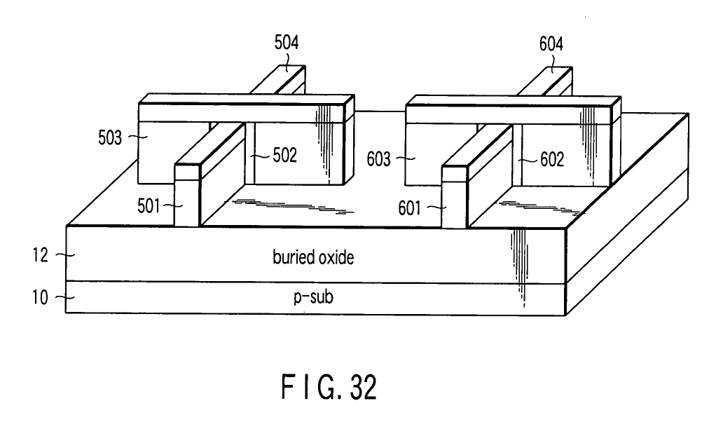

FIG. 32 is a perspective view schematically illustrating the structure of a FIN-type semiconductor device according to the fourteenth embodiment of this invention.

A Si oxide film (buried insulating film) 12 is formed on a p-type Si substrate 10. A Fin structure that forms the source-drain regions of transistors is formed on the Si oxide film. The fin structure is a double-layer one that is composed of a Si layer and a SiN layer. More specifically, a double-layer structure composed of a p-type, single-crystal Si layer 501a (lower layer) and an SiN layer 504 (upper layer) is provided in the nMOS transistor region. In the pMOS transistor region, a double-layer structure is provided, which is composed of an n-type, single-crystal Si layer 601 and a SiN layer 604. The Fin structure may have an insulating film other than a SiN film. Alternatively, it may be a single-layer structure, having no insulating films.

Gate electrodes 503 and 603 extend, crossing the Fin structure. A silicon oxide film is formed as gate insulating film 502 at the interface between the electrode 503 and the Fin structure. Similarly, a silicon oxide film is formed as gate insulating film 602 at the interface between the electrode 603 and the Fin structure. This configuration is known as double-gate MOS transistor, which has channels in both sides of the Fin part. If the Fin structure has a single-crystal Si layer, the upper part of the Fin part will be a channel region. In this case, a tri-gate MOS transistor is provided.

The gate electrodes 503 and 603 are made of TaGe2 oriented in the (102) direction, or perpendicular to the gate insulating films 502 and 602. They have been formed through heat treatment performed at 500° C. or less. Although not illustrated in FIG. 32, a source region and a drain region, both being n-type, high-concentration impurity regions, are formed in the p-type Fin. In the n-type Fin there are formed a source region and a drain region that are p-type, high-concentration impurity regions. In three-dimensional devices like the present embodiment, it is extremely difficult to distribute impurities uniformly in the direction of height. In view of this, the FIN-type semiconductor device according to this embodiment may assume a Schottky-source-drain structure as the sixth embodiment.

Even if the device assumes a Schottky-source-drain structure, however, the device remains a completely-depleted device like the SOI-MOS transistors according to the second embodiment. Its threshold value cannot be controlled by changing the impurity concentration of the channel or the impurity concentration of the high-impurity polycrystalline Si gate electrode. Nevertheless, the threshold value is effectively controlled by adjusting the work function of the gate electrode. The effective work function of Ta germanide used in this embodiment lies near center of the Si forbidden band. This is why the device can be used as an HP transistor and an LOP transistor.

The fourteenth embodiment has double-gate MOS transistors of Fin structure. The double-gate MOS transistors of Fin structure may be replaced by other types of three-dimensional devices, such as planer double-gate C-MOS transistors and vertical double C-MOS transistors.

### Fifteenth Embodiment

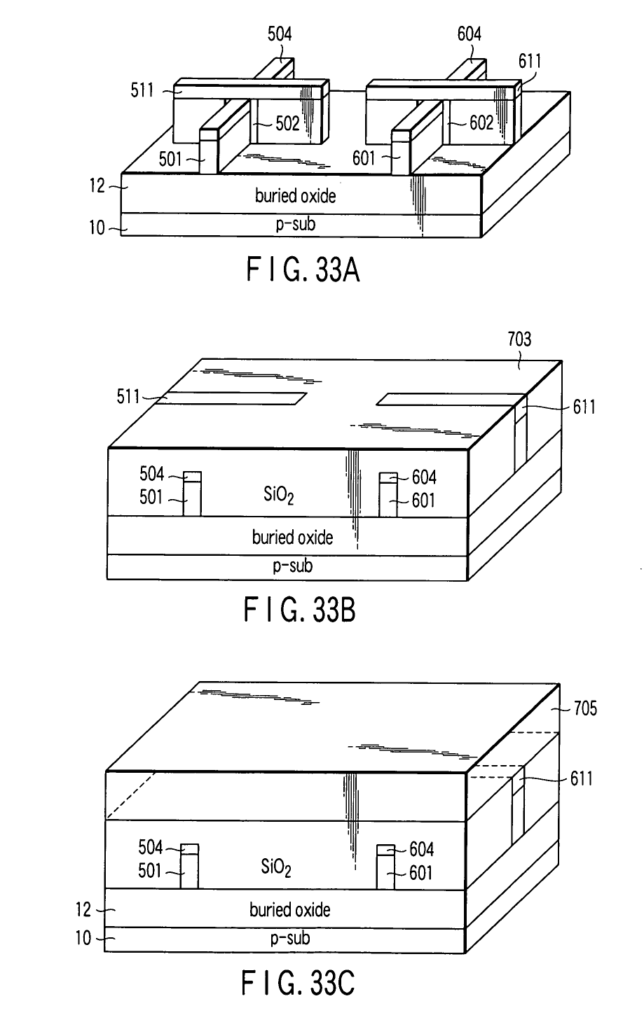

FIGS. 33A to 33C are perspective views showing a method of manufacturing the semiconductor device illustrated in FIG. 32.

First, a SOI substrate is prepared as shown in FIG. 33A. In the same way as in manufacturing the ordinary Fin structure, a Si nitride film, an Si oxide film and a Ge layer are deposited. Then, ion implantation, CMP and lithography are performed in combination, thereby forming a basic structure of the type depicted in FIG. 32. In FIGS. 33A to 33C, reference numerals 511 and 611 denote Ge layers, which will be processed into gate electrodes.

Next, as FIG. 33B shows, an Si oxide film 703 is deposited on the entire surface of the substrate. CMP is then carried out, exposing only the tops of the gate electrodes.

As FIG. 33C depicts, a Ta film 705 is formed by sputtering. The Ta film 705 is massive enough to change the gate electrodes to one made of germanide.

Thermal oxidation is then performed, changing only the gate electrode parts into germanide layers. Electrodes 503 and 603 made of Ta germanide are thereby formed. Thereafter, those parts of the Ta film 705 which remain not reacted are removed by etching. As a result, the structure of FIG. 32 is provided.

(Modifications)

The present invention is not limited to the embodiments described above. In each embodiment, the channel regions are made of Si. Nonetheless, the channel regions may be made of strained Si in which mobility is greater than in Si. Further, SiGe or strained SiGe may be used instead. As mentioned in describing some of the embodiments, the gate-electrode material according to this invention is useful, particularly for pMOS transistors. In view of this, this invention can be applied, not only to C-MOS devices, but also to semiconductor devices that have pMOS transistors. Moreover, the gate insulating films can be made of materials other than oxides. The present invention can therefore be applied, to not only MOS transistors but also MIS transistors.

In most embodiments described above, the gate electrodes are made of materials containing Ta and Ge. Nevertheless, Ta may be replaced by vanadium (V) or niobium (Nb). In this case, too, the same advantages can be expected. Furthermore, the method of manufacturing each embodiment is not limited to those shown in FIGS. 23A to 23D, FIGS. 24A to 24D, FIGS. 25A to 25D, FIGS. 26A to 26D, FIGS. 27A to 27D, FIGS. 28A to 28D, FIGS. 29A to 29D, FIGS. 30A to 30D, FIGS. 31A to 31D, and FIGS. 33A to 33C. The method may be changed, if necessary in accordance with the specification of the device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MIS-type semiconductor device comprising:
a semiconductor substrate; and
a p-type MIS transistor which is provided on the semiconductor substrate and which has a gate electrode containing Ge and one element selected from the group consisting of Ta, V and Nb.

2. The MIS-type semiconductor device according to claim 1, wherein the gate electrode contains 50% or less of N.

3. The MIS-type semiconductor device according to claim 1, wherein the gate electrode contains 10% or less of one element selected from the group consisting of B, As, P, In, Sb, S and Al.

4. The MIS-type semiconductor device according to claim 1, wherein the semiconductor substrate is formed of an SOI substrate.

5. The MIS-type semiconductor device according to claim 1, wherein the MIS transistor has a channel region which contains Ge.

6. The MIS-type semiconductor device according to claim 1, wherein the gate electrode is formed of a double-layer structure comprising an upper layer which contains Ge and a lower layer which contains Ge in a higher composition ratio than in the upper layer, which is 80% or more with respect to Si.

7. The MIS-type semiconductor device according to claim 1, wherein the semiconductor substrate is made of Si or Ge.

8. A MIS-type semiconductor device comprising:
a semiconductor substrate;
a p-type MIS transistor which is provided on the semiconductor substrate and which has a gate electrode containing Ge and one element selected from the group consisting of Ta, V and Nb; and
an n-type MIS transistor which is provided on the semiconductor substrate.

9. The MIS-type semiconductor device according to claim 8, wherein the p-type MIS transistor and the n-type MIS transistor respectively have a gate electrode which contains 50% or less of N.

10. The MIS-type semiconductor device according to claim 8, wherein the gate electrodes of the p-type MIS transistor and n-type MIS transistor contain 10% or less of one element selected from the group consisting of B, As, P, In, Sb, S and Al.

11. The MIS-type semiconductor device according to claim 8, wherein the semiconductor substrate is an SOI substrate.

12. The MIS-type semiconductor device according to claim 8, wherein the gate electrode of the p-type MIS transistor is made of germanide of Ta, V or Nb, and the gate electrode of the n-type MIS transistor is made of silicide of a metal element that configures the gate electrode of the p-type MIS transistor.

13. The MIS-type semiconductor device according to claim 8, wherein the gate electrode of the p-type MIS transistor is made of germanide of Ta, V or Nb, and the gate electrode of the n-type MIS transistor contains Al.

14. The MIS-type semiconductor device according to claim 8, wherein the gate electrode of the p-type MIS transistor and the gate electrode of the n-type MIS transistor are of the same composition.

15. The MIS-type semiconductor device according to claim 8, wherein the p-type MIS transistor and the n-type MIS transistor have a channel region each, which contains Ge.

16. The MIS-type semiconductor device according to claim 8, wherein the gate electrode is formed of a double-layer structure comprising an upper layer which contains Ge and a lower layer which contains Ge in a higher composition ratio than in the upper layer, which is 80% or more with respect to Si.

17. The MIS-type semiconductor device according to claim 8, wherein the semiconductor substrate is made of Si or Ge.

18. The MIS-type semiconductor device according to claim 8, wherein the p-type MIS transistor and the n-type MIS transistor comprise a complementary MIS device.

19. A complementary MIS semiconductor device comprising:
a semiconductor substrate;
an n-type well layer which is formed on the semiconductor substrate;
a p-type well layer which is formed on the semiconductor substrate;
an element-isolating insulating film formed on the semiconductor substrate to isolate the p-type well layer and the n-type well layer from each other;
a p-type MIS transistor which contains a gate electrode provided on an gate insulating film formed on the n-type well layer, and a p-type source-drain region formed in the n-type well layer, the gate electrode being made of Ta germanide; and
an n-type MIS transistor which has a gate electrode provided on an gate insulating film formed on the p-type well layer, and an n-type source-drain region formed in the p-type well layer, the gate electrode of the n-type MIS transistor being made of Ta silicide.

20. The complementary MIS semiconductor device according to claim 19, wherein the semiconductor substrate is formed of a SOI substrate.
